(19) United States
(12) Patent Application Publication
(10) Pub. No.: US 2025/0271298 A1
(43) Pub. Date: Aug. 28, 2025

(54) SENSOR, IMAGE SENSOR, DISPLAY PANEL, AND DEVICE

(71) Applicant: Samsung Electronics Co., Ltd., Suwon-si (KR)

(72) Inventors: Feifei FANG, Suwon-si (KR); Hyeong-Ju KIM, Suwon-si (KR); Tae Jin CHOI, Suwon-si (KR); Kyung Bae PARK, Suwon-si (KR); Jeong Il PARK, Suwon-si (KR); Sungyoung YUN, Suwon-si (KR); Younhee LIM, Suwon-si (KR)

(73) Assignee: Samsung Electronics Co., Ltd., Suwon-si (KR)

(21) Appl. No.: 19/049,528

(22) Filed: Feb. 10, 2025

(30) Foreign Application Priority Data
Feb. 23, 2024 (KR) 10-2024-0026690
Feb. 3, 2025 (KR) 10-2025-0013239

(51) Int. Cl. G01J 1/44; G01J 1/04; H10K 30/30; H10K 39/34; H10K 85/60

(52) U.S. Cl. CPC G01J 1/44; G01J 1/0492; H10K 85/6572; G01J 2001/446; H10K 30/30; H10K 39/34

(57) ABSTRACT

A sensor includes an anode; a cathode; an organic photoelectric conversion layer between the anode and the cathode; and a first organic auxiliary layer between the cathode and the organic photoelectric conversion layer. The organic photoelectric conversion layer includes a p-type semiconductor and an n-type semiconductor. The organic photoelectric conversion layer includes a first singlet fission material. A LUMO energy level of the first singlet fission material is equal to or deeper than a LUMO energy level of the n-type semiconductor. The first singlet fission material is represented by Chemical Formula 1:

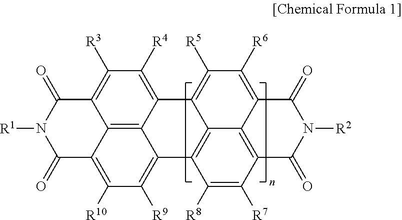

in the Chemical Formula 1, the definitions of R¹ to R¹⁰ and n are described in the specification.

### CROSS-REFERENCE TO RELATED APPLICATIONS

This application claims priority to and the benefit of Korean Patent Application No. 10-2024-0026690 filed with the Korean Intellectual Property Office on Feb. 23, 2024 and Korean Patent Application No. 10-2025-0013239 filed with the Korean Intellectual Property Office on Feb. 3, 2025, and the entire contents of each of which are incorporated herein by reference.

### BACKGROUND

### (a) Field

Example embodiments are directed to sensors, image sensors, display panels, and devices.

### (b) Description of the Related Art

A photoelectric conversion device is a device that absorbs light and converts the absorbed light into an electrical signal, and is applied to various fields that require optical properties. Silicon is a representative photoelectric conversion material configured to absorb light and convert the absorbed light into an electrical signal, and may be used with a color filter to exhibit wavelength selectivity. Photoelectric conversion devices may be used as sensors due to their photoelectric conversion characteristics and wavelength selectivity.

### SUMMARY

Recently, in order to increase a resolution of sensors, it is required to integrate many pixels per unit area. Accordingly, the size of each pixel becomes smaller, and as a result, the absorption area of silicon within each pixel is not sufficient, which limits the ability to achieve high sensitivity.

Some example embodiments provide a sensor with high integration and high sensitivity characteristics.

Some example embodiments provide an image sensor including the sensor.

Some example embodiments provide a display panel including the sensor.

Some example embodiments provide a device including the sensor, the image sensor, or the display panel.

According to some example embodiments, a sensor includes an anode; a cathode; and a first organic auxiliary layer between the cathode and the organic photoelectric conversion layer. The organic photoelectric conversion layer may include a p-type semiconductor and an n-type semiconductor. The first organic auxiliary layer may include a first singlet fission material. A LUMO energy level of the first singlet fission material may be equal to or deeper than a LUMO energy level of the n-type semiconductor. The first singlet fission material may be represented by Chemical Formula 1:

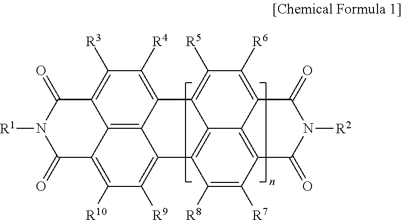

wherein, in the Chemical Formula 1,
R¹ to R¹⁰ may each independently be hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a substituted or unsubstituted silyl group, a substituted or unsubstituted amine group, a halogen, a cyano group, or any combination thereof,
R¹ to R¹⁰ may each be independently present or two adjacent ones among R¹ to R¹⁰ may be linked to form a ring, and n may be an integer from 0 to 3.

The first organic auxiliary layer may be in contact with the organic photoelectric conversion layer.

The LUMO energy level of the first singlet fission material may be between the LUMO energy level of the n-type semiconductor and a work function of the cathode.

The first singlet fission material and at least one of the p-type semiconductor or the n-type semiconductor may be each a wavelength selective organic material configured to selectively absorb light of a first wavelength spectrum selected from a blue wavelength spectrum, a green wavelength spectrum, a red wavelength spectrum, and an infrared wavelength spectrum.

The first singlet fission material and the at least one of the p-type semiconductor or the n-type semiconductor may be each an organic material configured to absorb light in the green wavelength spectrum, and a wavelength (λ_{max, EQE}) exhibiting the maximum external quantum efficiency of the sensor and a wavelength (λ_{max, IQE}) exhibiting the maximum internal quantum efficiency each belong to about 510 nm to about 580 nm.

The sensor may further include an electron auxiliary layer between the first organic auxiliary layer and the cathode, wherein a HOMO energy level of the electron auxiliary layer may be deeper than each of a work function of the cathode and a HOMO energy level of the p-type semiconductor.

The sensor may further include a second organic auxiliary layer between the anode and the organic photoelectric conversion layer, wherein the second organic auxiliary layer may include a second singlet fission material different from the first singlet fission material.

The second singlet fission material may be an organic material that satisfies Relation Formula 1:

$$E ( {S}_{1} ) + 0.5 eV \geq 2 \times E ( {T}_{1} ) \qquad [ Relation Formula 1 ]$$

wherein, in Relation Formula 1,
E(S₁) is an excitation energy in a lowest singlet excited state of the second singlet fission material,
E(T₁) is an excitation energy in a lowest triplet excited state of the second singlet fission material, and E(S₁) and E(T₁) are DFT calculation values.

The p-type semiconductor and the n-type semiconductor each may not satisfy an energy level of the Relation Formula 1.

The second organic auxiliary layer may be in contact with the organic photoelectric conversion layer, and a HOMO energy level of the second singlet fission material may be equal to or shallower than a HOMO energy level of the p-type semiconductor.

The HOMO energy level of the second singlet fission material may be between the HOMO energy level of the p-type semiconductor and a work function of the anode.

The sensor may further include a hole auxiliary layer between the second organic auxiliary layer and the anode, and a LUMO energy level of the hole auxiliary layer may be shallower than each of a work function of the anode and the LUMO energy level of the n-type semiconductor.

According to some example embodiments, an image sensor may include a substrate, and the sensor on the substrate.

The image sensor may further include a first photodiode and a second photodiode within the substrate, wherein the first photodiode and the second photodiode may each overlap the sensor along a thickness direction of the substrate.

The image sensor may further include a first color filter between the sensor and the first photodiode, and a second color filter between the sensor and the second photodiode.

The sensor may include a first sensor configured to photoelectrically convert light of a first wavelength spectrum selected from a red wavelength spectrum, a green wavelength spectrum, and a blue wavelength spectrum, a second sensor configured to photoelectrically convert light of a second wavelength spectrum selected from the red wavelength spectrum, the green wavelength spectrum, and the blue wavelength spectrum, and a third sensor configured to photoelectrically convert light of a third wavelength spectrum selected from the red wavelength spectrum, the green wavelength spectrum, and the blue wavelength spectrum, wherein the first wavelength spectrum, the second wavelength spectrum, and the third wavelength spectrum may be different from each other, and wherein the first sensor, the second sensor, and the third sensor may be stacked along a thickness direction of the substrate.

According to some example embodiments, a display panel may include a substrate, a light emitting element array on the substrate, the light emitting element array including a blue light emitting element configured to emit light in a blue wavelength spectrum, a green light emitting element configured to emit light in a green wavelength spectrum, and a red light emitting element configured to emit light in a red wavelength spectrum, and a sensor array on the substrate, the sensor array including the sensor.

According to some example embodiments, a device including the sensor, the image sensor, or the display panel is provided.

Sensitivity of the sensor may be increased by simultaneously improving the external quantum efficiency and the internal quantum efficiency of the sensor while reducing the size of the sensor.

### BRIEF DESCRIPTION OF THE DRAWINGS

FIG. 1 is a cross-sectional view showing a sensor according to some example embodiments,

FIG. 2 is a cross-sectional view showing a sensor according to some example embodiments,

FIG. 3 is a cross-sectional view showing a sensor according to some example embodiments,

FIG. 4 is a cross-sectional view showing a sensor according to some example embodiments,

FIG. 5 is a cross-sectional view showing an image sensor according to some example embodiments,

FIG. 6 is a plan view showing an image sensor according to some example embodiments,

FIG. 7 is a cross-sectional view showing the image sensor of FIG. 6 according to some example embodiments,

FIG. 8 is a cross-sectional view showing the image sensor of FIG. 6 according to some example embodiments,

FIG. 9 is a plan view showing an image sensor according to some example embodiments,

FIG. 10 is a cross-sectional view showing the image sensor of FIG. 9 according to some example embodiments,

FIG. 11 is a plan view showing a sensor-embedded display panel according to some example embodiments,

FIG. 12 is a cross-sectional view showing a sensor-embedded display panel according to some example embodiments,

FIG. 13 is a schematic view showing a smart phone as an electronic device according to some example embodiments,

FIG. 14 is a schematic view illustrating an electronic device according to some example embodiments, and

FIG. 15 is a schematic view showing an optical communication device as an electronic device according to some example embodiments.

### DETAILED DESCRIPTION

Hereinafter, some example embodiments of the present inventive concepts will be described in detail so that a person skilled in the art would understand the same. However, the inventive concepts may be embodied in many different forms and is not to be construed as limited to the example embodiments set forth herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity, and the same or similar constituent elements are indicated by the same reference numeral throughout the specification.

Hereinafter, the terms “lower portion” and “upper portion” are for convenience of description and do not limit the positional relationship.

As used herein, when a definition is not otherwise provided, “substituted” refers to replacement of a hydrogen atom of a compound by a substituent selected from a halogen atom, a hydroxyl group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, phosphoric acid or a salt thereof, a silyl group, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and any combination thereof.

As used herein, when a definition is not otherwise provided, “hetero” refers to one including 1 to 4 heteroatoms selected from N, O, S, Se, Te, Si, and P.

Hereinafter, “combination” refers to a mixture of two or more and a stack structure of two or more.

It will further be understood that when an element is referred to as being “on” another element, it may be above or beneath or adjacent (e.g., horizontally adjacent) to the other element. It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of +10%). Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of +10%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of +10%).

It will be understood that elements and/or properties thereof may be recited herein as being “identical” to, “the same” or “equal” as other elements and/or properties, and it will be further understood that elements and/or properties thereof recited herein as being “identical” to, “the same” as, or “equal” to other elements and/or properties may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances.

Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or value is referred to as being the same as another element or value, it should be understood that an element or a value is the same as another element or value within a desired manufacturing or operational tolerance range (e.g., +10%).

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

Hereinafter, a sensor according to some example embodiments will be described.

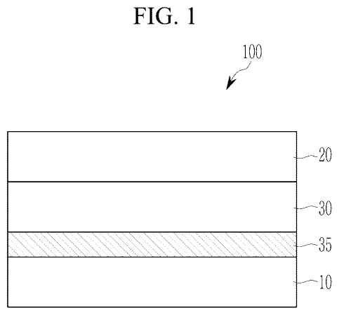

FIG. 1 is a cross-sectional view showing an example of a sensor according to some example embodiments.

Referring to FIG. 1, the sensor 100 according to some example embodiments includes a cathode 10, an anode 20, a photoelectric conversion layer 30, and a first organic auxiliary layer 35.

A substrate (not shown) may be disposed under the cathode 10 or on the anode 20. The substrate may be, for example, an inorganic substrate such as glass; a polymer substrate including polycarbonate, polymethyl methacrylate, polyethylene terephthalate, polyethylene naphthalate, polyimide, polyamide, polyamidoimide, polyethersulfone, or combinations thereof; or a semiconductor substrate such as a silicon wafer or semiconductor compound. The substrate may be omitted.

At least one of the cathode 10 or the anode 20 may be a light transmitting electrode. The transparent electrode may be a transparent electrode or a semi-transmissive electrode. The transparent electrode may have a light transmittance of about 85% to about 100%, about 90% to about 100%, or about 95% to about 100% for light in the visible light wavelength region, and the semi-transmissive electrode may have a light transmittance of greater than or equal to about 30% and less than about 85%, about 40% to about 80%, or about 40% to about 75% of light in the visible light wavelength region. The transparent electrode and the semi-transmissive electrode may include, for example, at least one of an oxide conductor, a carbon conductor, or a metal thin film. The oxide conductors may include, for example, one or more of indium tin oxide (ITO), indium zinc oxide (IZO), zinc tin oxide (ZTO), aluminum tin oxide (ATO), or aluminum zinc oxide (AZO), the carbon conductor may include one or more selected from graphene and carbon nanostructures, and the metal thin film may be a very thin film including aluminum (AI), magnesium (Mg), silver (Ag), gold (Au), magnesium-silver (Mg—Ag), magnesium-aluminum (Mg-AI), an alloy thereof, or any combination thereof.

One of the cathode 10 or the anode 20 may be a reflective electrode. For example, the reflective electrode may have a low light transmittance of less than about 10% and/or a high reflectance of greater than or equal to about 50% for light in the visible light wavelength range. The reflective electrode may include an optically opaque material, such as a metal, a metal alloy, a nitride thereof, or any combination thereof, for example aluminum (AI), silver (Ag), gold (Au), titanium (Ti), an alloy thereof, a nitride thereof, or any combination thereof.

For example, the cathode 10 may be a light transmitting electrode and the anode 20 may be a light transmitting electrode or a reflective electrode. For example, the cathode 10 may be a light-receiving electrode or an incident electrode disposed on the side where light enters.

The photoelectric conversion layer 30 is between the cathode 10 and the anode 20.

The photoelectric conversion layer 30 may be configured to absorb light of a portion of the wavelength spectrum and convert the absorbed light into an electrical signal, and for example, it may be configured to selectively absorb light of one wavelength spectrum selected from the red wavelength spectrum, the green wavelength spectrum, the blue wavelength spectrum, or the infrared wavelength spectrum and convert the absorbed light into an electrical signal. Herein, selectively absorbing light of one wavelength spectrum selected from the red wavelength spectrum, the green wavelength spectrum, the blue wavelength spectrum, or the infrared wavelength spectrum means that the peak absorption wavelength (λ_{peak,A}) of the absorption spectrum exists in one of greater than about 600 nm and less than or equal to about 700 nm (red wavelength spectrum), about 500 nm to about 600 nm (green wavelength spectrum), greater than or equal to about 380 nm and less than 500 nm (blue wavelength spectrum), and greater than about 700 nm and less than or equal to 3000 nm (infrared wavelength spectrum) and a light absorption amount within the corresponding wavelength spectrum is significantly higher than a light absorption amount in the other wavelength spectrum. The significantly higher light absorption amount of the wavelength spectrum may mean that an area of the absorption spectrum in the corresponding wavelength spectrum based on a total area of the absorption spectrum is for example greater than or equal to about 70%, greater than or equal to about 75%, greater than or equal to about 80%, greater than or equal to about 85%, greater than or equal to about 90%, or greater than or equal to about 95%.

The photoelectric conversion layer 30 may include at least one p-type semiconductor and at least one n-type semiconductor forming a pn junction, and at least one p-type semiconductor and at least one n-type semiconductor may receive light from the outside (e.g., an external environment external to the sensor 100) to generate excitons and then separate the generated excitons into holes and electrons. At least one of the p-type semiconductor or the n-type semiconductor may be an organic material, and accordingly, the photoelectric conversion layer 30 may be an organic photoelectric conversion layer.

At least one of the p-type semiconductor or the n-type semiconductor may be a light absorbing material. For example, each of the p-type semiconductor and the n-type semiconductor may be a light absorbing material. At least one of the p-type semiconductor or the n-type semiconductor may be an organic light absorption material. For example, each of the p-type semiconductor and the n-type semiconductor may be an organic light absorption material.

For example, at least one of the p-type semiconductor or the n-type semiconductor may be a wavelength-selective light absorbing material configured to selectively absorb light in a particular (or, alternatively, predetermined) wavelength regions. For example, at least one of the p-type semiconductor or the n-type semiconductor may be a wavelength-selective organic light-absorbing material. The p-type semiconductor and the n-type semiconductor may have peak absorption wavelengths (λ_{peak,A}) in the same or different wavelength regions.

As an example, the p-type semiconductor may be an organic material with a core structure including an electron donating moiety and an electron accepting moiety. As an example, the p-type semiconductor may be an organic material with a core structure that includes an electron donating moiety and an electron accepting moiety and additionally includes a IT-conjugation linking group linking the electron donating moiety and the electron accepting moiety.

For example, the p-type semiconductor may be represented by Chemical Formula A or B, but is not limited thereto.

EDG-EAG [Chemical Formula A]

EDG-HA-EAG [Chemical Formula B]

In Chemical Formulas A and B,
EDG may be an electron donating group,
EAG may be an electron accepting group, and
HA may be a TT-conjugation linking group, and may be, for example, a substituted or unsubstituted C6 to C20 arylene group or a C2 to C30 heterocyclic group having at least one of S, Se, Te, or Si.

For example, the p-type semiconductor may be represented by Chemical Formula B-1.

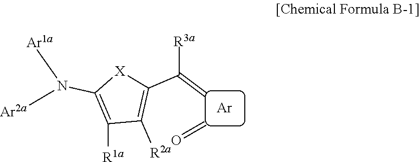

In Chemical Formula B-1,
X may be CR′=CR″, S, Se, Te, SO, SO₂, or SiR^{a}R^{b},
Ar may be a substituted or unsubstituted C6 to C30 arylene group, a substituted or unsubstituted C3 to C30 heterocyclic group, or a fused ring of the foregoing two or more,
Ar^{1a} and Ar^{2a} may each independently be a substituted or unsubstituted C6 to C30 aryl group or a substituted or unsubstituted C3 to C30 heteroaryl group,
R^{1a} to R^{3a}, R′, R″, R^{a}, and R^{b} may each independently be hydrogen, deuterium, a substituted or unsubstituted C1 to C30 alkyl group, a substituted or unsubstituted C6 to C30 aryl group, a substituted or unsubstituted C3 to C30 heteroaryl group, a substituted or unsubstituted C1 to C30 alkoxy group, a halogen, or a cyano group, and
Ar^{1a}, Ar^{2a}, R^{1a} and R^{2a} may each be independently present or two adjacent ones of Ar^{1a}, Ar^{2a}, R^{1a} and R^{2a} may be linked to each other to form a ring.

For example, in Chemical Formula B-1, Ar^{1a} and Ar^{2a} may each independently be one of a substituted or unsubstituted phenyl group, a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyridazinyl group, a substituted or unsubstituted pyrimidinyl group, a substituted or unsubstituted pyrazinyl group, a substituted or unsubstituted quinolinyl group, a substituted or unsubstituted isoquinolinyl group, a substituted or unsubstituted naphthyridinyl group, a substituted or unsubstituted cinnolinyl group, a substituted or unsubstituted quinazolinyl group, a substituted or unsubstituted phthalazinyl group, a substituted or unsubstituted benzotriazinyl group, a substituted or unsubstituted pyridopyrazinyl group, a substituted or unsubstituted pyridopyrimidinyl group, or a substituted or unsubstituted pyridopyridazinyl group.

As an example, two adjacent ones of Ar^{1a}, Ar^{2a}, R^{1a} and R^{2a} in Chemical Formula B-1 may be linked to each other to form a ring, and two adjacent ones of Ar^{1a},
Ar^{2a}, R^{1a} and R^{2a} may be, for example, linked by a single bond, —(CR^{g}R^{h})ₙ₁-(n1 is 1 or 2), —O—, —S—, —Se—, —N═, —NRⁱ—, —SiRⁱR^{k}—, —GeR^{l}R^{m}—, and a divalent hydrocarbon group to form a ring. Herein R^{g} to R^{m} may each independently be hydrogen, a substituted or unsubstituted C1 to C30 alkyl group, a substituted or unsubstituted C6 to C30 aryl group, a substituted or unsubstituted C3 to C30 heteroaryl group, a substituted or unsubstituted C1 to C30 alkoxy group, a halogen, or a cyano group.

As an example, the p-type semiconductor may be represented by Chemical Formula B-1a or B-1b.

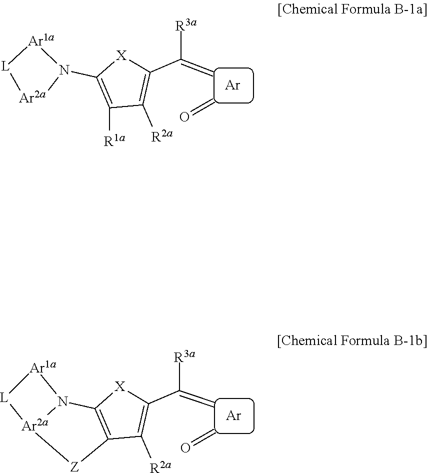

In Chemical Formulas B-1a and B-1b,
X, Ar, Ar^{1a}, Ar^{2a}, and R^{1a} to R^{3a} are the same as X, Ar, Ar^{1a}, Ar^{2a}, and R^{1a} to R^{3a} as described above with reference to Chemical Formula B-1, respectively, and
L and Z may each independently be a single bond, O, S, Se, Te, SO, SO₂, —(CR^{g}R^{h})ₙ₁-(n1 is 1 or 2), —N═, —NRⁱ—, —SiRⁱR^{k}—, and —GeR^{l}R^{m}—, a substituted or unsubstituted C1 to C30 alkylene group, a substituted or unsubstituted C3 to C30 cycloalkylene group, a substituted or unsubstituted C6 to C30 arylene group, or any combination thereof, where R^{g} to R^{m} may each independently be hydrogen, a substituted or unsubstituted C1 to C30 alkyl group, a substituted or unsubstituted C6 to C30 aryl group, a substituted or unsubstituted C3 to C30 heteroaryl group, a substituted or unsubstituted C1 to C30 alkoxy group, a halogen, or a cyano group.

As an example, the n-type semiconductor may be fullerene or a fullerene derivative. Examples of the fullerene may include C60, C70, C76, C78, C80, C82, C84, C90, C96, C240, C540, a mixture thereof, a fullerene nanotube, and the like. The fullerene derivative may refer to compounds of these fullerenes having a substituent thereof. The fullerene derivative may include a substituent such as an alkyl group (e.g., C1 to C30 alkyl group), an aryl group (e.g., C6 to C30 aryl group), a heterocyclic group (e.g., C3 to C30 heterocycloalkyl group), and the like. Examples of the aryl groups and heterocyclic groups may be a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, a isobenzofuran ring, a benzimidazole ring, a imidazopyridine ring, a quinolizidine ring, a quinoline ring, a phthalazine ring, a naphthyridine ring, a quinoxaline ring, an isoquinoline ring, a carbazole ring, a phenanthridine ring, an acridine ring, a phenanthroline ring, a thianthrene ring, a chromene ring, an xanthene ring, a phenoxazine ring, a phenoxathiin ring, a phenothiazine ring, or a phenazine ring.

For example, the n-type semiconductor may be a transparent material that does not absorb light in the visible wavelength spectrum (e.g., is configured to not absorb any light in the visible wavelength spectrum), for example, a transparent organic material. The transparent material (or transparent organic material) may have a wide energy bandgap such that it does not substantially absorb light in the visible wavelength spectrum, and it may have, for example, an energy bandgap of greater than or equal to about 2.5 eV, within this range, for example, an energy bandgap of about 2.5 eV to about 6.0 eV.

The photoelectric conversion layer 30 may include an intrinsic layer (I layer) in which a p-type semiconductor and an n-type semiconductor are mixed in a bulk heterojunction form. Herein, the p-type semiconductor and the n-type semiconductor may be mixed in a volume ratio of about 1:9 to about 9:1, and may be mixed within the range, for example, in a volume ratio of about 2:8 to about 8:2, in a volume ratio of about 3:7 to about 7:3, in a volume ratio of about 4:6 to about 6:4, or in a volume ratio of about 5:5.

The photoelectric conversion layer 30 may include a bilayer including a p-type layer including the aforementioned p-type semiconductor and an n-type layer including the aforementioned n-type semiconductor. Herein, a thickness ratio of the p-type layer and the n-type layer may be about 1:9 to about 9:1, for example about 2:8 to about 8:2, about 3:7 to about 7:3, about 4:6 to about 6:4, or about 5:5.

The photoelectric conversion layer 30 may include an intrinsic layer (I layer), a p-type layer, and/or an n-type layer. For example, the photoelectric conversion layer 30 may be included in various combinations such as p-type layer/l layer, I layer/n-type layer, and p-type layer/l layer/n-type layer.

A thickness of the photoelectric conversion layer 30 may be about 5 nm to about 1 μm, and within the above range, about 5 nm to about 800 nm, about 10 nm to about 600 nm, or about 10 nm to about 300 nm.

The first organic auxiliary layer 35 is between the cathode 10 and the photoelectric conversion layer 30. The first organic auxiliary layer 35 may be in contact with one surface (for example, the upper surface or the lower surface) of the photoelectric conversion layer 30 and may be between the cathode 10 and the photoelectric conversion layer 30.

The first organic auxiliary layer 35 may include a singlet fission material (also referred to herein interchangeably as a first singlet fission material). The singlet fission material may be an organic light absorbing material configured to exhibit a phenomenon that the exciton in the singlet state (hereinafter referred to as “singlet exciton”) generated by absorbing one photon is divided into two excitons in the triplet state (hereinafter referred to as “triplet exciton”).

The singlet fission material be an organic material. The singlet fission material may satisfy Relation Formula 1 to exhibit this singlet fission.

$$E ( {S}_{1} ) + 0.5 eV \geq 2 \times E ( {T}_{1} ) \qquad [ Relation Formula 1 ]$$

In Relation Formula 1,
E(S₁) is an excitation energy in a lowest singlet excited state of the singlet fission material, and
E(T₁) is the excitation energy in a lowest triplet excited state of the singlet fission material. In Relation Formula 1, E(S₁) may be an energy required to be excited from a ground state (S₀) to the lowest single excited state (S₁), and E(T₁) may be an energy required to be excited from the ground state (S₀) to the lowest triplet excited state (T₁).

For example, E(S₁) may be an excitation energy in a lowest singlet excited state of the singlet fission material, and E(T₁) may be an excitation energy in a lowest triplet excited state of the singlet fission material. E(S₁) and E(T₁) may be calculation values of density functional theory (DFT), for example DFT calculation values, and specifically, calculation values obtained from DGDZVP basis sets under B3LYP functional conditions.

A singlet fission material satisfying Relation Formula 1 may be configured to absorb light which splits from the excited singlet state (S₁) to the triplet state (T₁) and generates amplified (e.g., approximately double) excitons, and these amplified excitons may be combined with the excitons generated from the photoelectric conversion layer 30 to increase an amount of carrier charges and thus increase efficiency of the sensor 100, wherein theoretically greater than about 100% of external quantum efficiency (EQE) and internal quantum efficiency (IQE) may be realized.

As a result, based on including the first organic auxiliary layer 35 that includes a singlet fission material, the sensor 100 may be configured to exhibit improved photoelectric conversion performance and/or efficiency, where such improved performance and/or efficiency may enable reduced power consumption by the sensor 100 without compromising photoelectric conversion performance (e.g., sensitivity) by the sensor 100, reduced absorption area of the sensor 100 without compromising photoelectric conversion performance (e.g., sensitivity) by the sensor 100 and thus enabling miniaturization with reduced absorption area of a pixel comprising the sensor 100 to thereby enable improved resolution of an image sensor array including a plurality of such pixels comprising one or more sensors 100, or any combination thereof.

The singlet fission material may be different respectively from the p-type semiconductor and the n-type semiconductor of the photoelectric conversion layer 30. For example, the p-type semiconductor and the n-type semiconductor of the photoelectric conversion layer 30 respectively may not satisfy Relation Formula 1 (e.g., may not satisfy an energy level of the Relation Formula 1).

The singlet fission material may be configured to absorb light of at least one spectrum of a red wavelength spectrum, a green wavelength spectrum, a blue wavelength spectrum, or an infrared wavelength spectrum. For example, the singlet fission material may have an overlapped absorption spectrum with that of the p-type semiconductor and/or the n-type semiconductor of the photoelectric conversion layer 30.

For example, in example embodiments where the p-type semiconductor and/or the n-type semiconductor is a material configured to selectively absorb light of a first wavelength spectrum selected from a red wavelength spectrum, a green wavelength spectrum, a blue wavelength spectrum, and an infrared wavelength spectrum, the singlet fission material may be a light-absorbing material configured to absorb light of the first wavelength spectrum. Accordingly, the sensor 100 may implement the enhanced electrical characteristics in a relatively narrow wavelength region (e.g., a narrow full width half maximum FWHM) belonging to the common wavelength region of the photoelectric conversion layer 30 and the first organic auxiliary layer 35.

The first wavelength spectrum may be, for example, a green wavelength spectrum, but is not limited thereto.

For example, the p-type semiconductor and/or the n-type semiconductor in the photoelectric conversion layer 30 and the singlet fission material in the first organic auxiliary layer 35 may be configured to selectively absorb light of a green wavelength spectrum. This common absorption wavelength spectrum may correspond to the sensing wavelength of the sensor 100.

For example, the wavelength (λ_{max,EQE}) exhibiting the maximum external quantum efficiency EQE of the sensor 100 and the wavelength (λ_{max,IQE}) representing the maximum internal quantum efficiency IQE may belong to the green wavelength spectrum, for example, about 510 nm to 580 nm, about 520 nm to 570 nm, about 520 nm to 560 nm, or about 525 nm to 550 nm.

Accordingly, the sensor 100 may implement the enhanced electrical characteristics described above in a relatively narrow wavelength region (e.g., a narrow FWHM) belonging to the green wavelength spectrum, based on the sensor 100 including the first organic auxiliary layer 35 including the singlet fission material.

The singlet fission material may have an energy level at which the electrons generated from the amplified excitons described above and the excitons generated from the photoelectric conversion layer 30 are easily able to move toward the cathode 10.

For example, the singlet fission material included in the first organic auxiliary layer 35 may have an equal or deeper LUMO energy level, compared with that of the n-type semiconductor included in the photoelectric conversion layer 30. For example, the LUMO energy level of the singlet fission material included in the first organic auxiliary layer 35 may be equal to or deeper than the LUMO energy level of the n-type semiconductor included in the photoelectric conversion layer 30. For example, the LUMO energy level of the singlet fission material included in the first organic auxiliary layer 35 may be between the LUMO energy level of the n-type semiconductor included in the photoelectric conversion layer 30 and a work function of the cathode 10. In other words, the LUMO energy level of the n-type semiconductor included in the photoelectric conversion layer 30, the LUMO energy level of the singlet fission material included in the first organic auxiliary layer 35, and the work function of the cathode 10 may have cascading energy levels.

For example, the LUMO energy level of the n-type semiconductor included in the photoelectric conversion layer 30 and the LUMO energy level of the singlet fission material included in the first organic auxiliary layer 35 may have a difference (absolute value reference) of greater than or equal to about 0 eV and less than about 1.0 eV and within the range, about 0 eV to about 0.8 eV, about 0 eV to about 0.7 eV, about 0 eV to about 0.5 eV, about 0 eV to about 0.3 eV, or about 0 eV to about 0.2 eV.

For example, the singlet fission material included in the first organic auxiliary layer 35 may be an organic compound represented by Chemical Formula 1. The singlet fission material included in the first organic auxiliary layer 35 may be an organic compound represented by Chemical Formula 1 while satisfying the aforementioned Relation Formula 1 and/or the aforementioned energy levels (e.g., the aforementioned LUMO energy level in relation to the LUMO energy level of the n-type semiconductor of the photoelectric conversion layer 30).

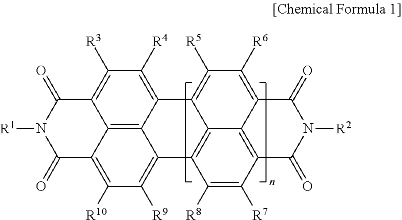

In Chemical Formula 1,
R¹ to R¹⁰ may each independently be hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a substituted or unsubstituted silyl group, a substituted or unsubstituted amine group, a halogen, a cyano group, or any combination thereof,
R¹ to R¹⁰ may each be independently present or two adjacent ones among R¹ to R¹⁰ may be linked to form a ring, and
n may be an integer from 0 to 3.

For example, R¹ to R¹⁰ may each independently be hydrogen, a substituted or unsubstituted methyl group, a substituted or unsubstituted ethyl group, a substituted or unsubstituted propyl group, a substituted or unsubstituted butyl group, a substituted or unsubstituted pentyl group, a substituted or unsubstituted hexyl group, a substituted or unsubstituted phenyl group, a substituted or unsubstituted biphenyl group, a substituted or unsubstituted naphthyl group, or any combination thereof.

For example, n may be 1.

For example, the singlet fission material included in the first organic auxiliary layer 35 may be an organic compound listed in Table 1 below, but is not limited thereto.

TABLE 1

| | | HOMO (eV) | LUMO (eV) | E (S₁, eV) | E (T₁, eV) |
|---|---|---|---|---|---|
| 1A | 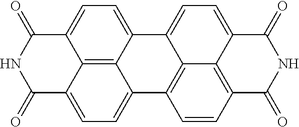 [SMILES: O=C1NC(=O)c2ccc3c4ccc5c6c(ccc(c7ccc1c2c73)c64)C(=O)NC5=O] | 6.38 | 4.44 | 2.549 | 1.494 |
| 1B | 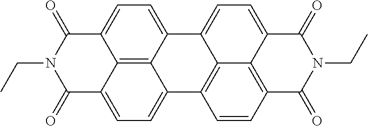 [SMILES: CCN1C(=O)c2ccc3c4ccc5c6c(ccc(c7ccc(c2c37)C1=O)c64)C(=O)N(CC)C5=O] | 6.50 | 4.25 | 2.537 | 1.486 |
| 1C | 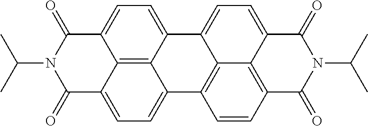 [SMILES: CC(C)N1C(=O)c2ccc3c4ccc5c6c(ccc(c7ccc(c2c37)C1=O)c64)C(=O)N(C(C)C)C5=O] | 6.37 | 4.28 | 2.534 | 1.482 |
| 1D | 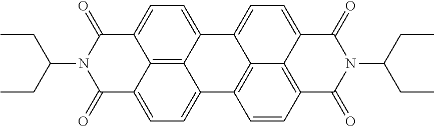 [SMILES: CCC(CC)N1C(=O)c2ccc3c4ccc5c6c(ccc(c7ccc(c2c37)C1=O)c64)C(=O)N(C(CC)CC)C5=O] | 6.50 | 4.37 | 2.533 | 1.482 |

The sensor 100 may further include the first organic auxiliary layer 35 including an organic compound represented by Chemical Formula 1 while satisfying the above-described Relation Formula 1 and energy levels to generate an amplified (e.g., approximately double) exciton as described above while also having good electron transfer characteristics, thereby implementing a sensor 100 showing improved external quantum efficiency (EQE) and internal quantum efficiency (IQE) in a relatively narrow wavelength region (e.g., narrow FWHM). Thus, a high-sensitivity sensor 100 may be implemented based on the sensor 100 including the first organic auxiliary layer 35 that includes the singlet fission material. As a result, the sensor 100 may have improved photoelectric conversion performance and/or power consumption efficiency, for example being configured to perform photoelectric conversion of incident light with reduced power consumption without compromising the photoelectric conversion performance of the sensor 100.

The thickness of the first organic auxiliary layer 35 may be the same as or thinner than the thickness of the photoelectric conversion layer 30, and may be, for example, about 1 nm to about 500 nm, and within the above range, about 2 nm to about 300 nm, about 5 nm to about 200 nm, about 5 nm to about 100 nm, about 10 nm to about 80 nm, or about 10 nm to about 50 nm.

Hereinafter, another example of a sensor according to some example embodiments will be described.

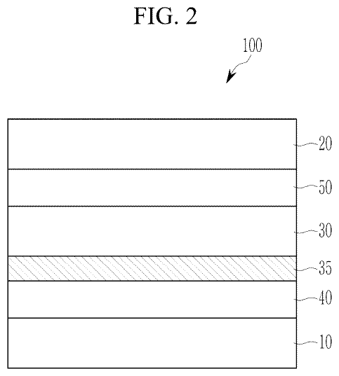

FIG. 2 is a cross-sectional view showing an example of a sensor according to some example embodiments.

Referring to FIG. 2, the sensor 100 according to some example embodiments, like the aforementioned example embodiments shown in FIG. 1, includes a cathode 10, an anode 20, a photoelectric conversion layer 30, and a first organic auxiliary layer 35. Descriptions of the cathode 10, the anode 20, the photoelectric conversion layer 30, and the first organic auxiliary layer 35 are as described above with reference to FIG. 1.

However, unlike some example embodiments, including the aforementioned example embodiments shown in FIG. 1, the sensor 100 according to some example embodiments, including the example embodiments shown in FIG. 2, further includes electron auxiliary layer 40 and hole auxiliary layer 50.

The electron auxiliary layer 40 may be between the cathode 10 and the first organic auxiliary layer 35, for example, one surface of the electron auxiliary layer 40 may be in contact with the cathode 10, and the other surface (e.g., opposite surface) of the electron auxiliary layer 40 may be in contact with the first organic auxiliary layer 35.

The electron auxiliary layer 40 may effectively increase the extraction of electrons moving from the photoelectric conversion layer 30 to the cathode 10 through the first organic auxiliary layer 35 and/or may effectively reduce, minimize, or prevent reverse movement of holes from the cathode 10 to the photoelectric conversion layer 30 through the first organic auxiliary layer 35, thereby improving the image sensing performance and/or efficiency (e.g., sensitivity) of the sensor 100. As a result, the sensor 100 may have improved photoelectric conversion performance and/or power consumption efficiency, for example being configured to perform photoelectric conversion of incident light with reduced power consumption without compromising the photoelectric conversion performance of the sensor 100.

For example, the HOMO energy level of the electron auxiliary layer 40 may be deeper than the work function of the cathode 10 and the HOMO energy level of the p-type semiconductor of the photoelectric conversion layer 30, respectively (e.g., deeper that each of the work function of the cathode 10 and the HOMO energy level of the p-type semiconductor of the photoelectric conversion layer 30), and may be additionally deeper than the HOMO energy level of the singlet fission material of the first organic auxiliary layer 35. For example, the HOMO energy level of the electron auxiliary layer 40 may be deeper than the work function of the cathode 10 and the HOMO energy level of the p-type semiconductor of the photoelectric conversion layer 30, respectively, in the range of about 0 to about 2.5 eV, about 0.2 eV to about 2.2 eV, about 0.4 eV to about 2.0 eV, or about 0.5 eV to about 1.8 eV. Accordingly, it is possible to effectively block the reverse movement of holes from the cathode 10 to the photoelectric conversion layer 30 through the first organic auxiliary layer 35.

The electron auxiliary layer 40 may include, for example, organic materials, inorganic materials, and/or organic and inorganic materials. The electron auxiliary layer 40 may be, for example, made of a metal halide such as LiF, NaCl, CsF, RbCl, and RbI; a metal oxide such as Li₂O and BaO; Liq (lithium quinolate), Alq₃ (tris(8-hydroxyquinolinato)aluminum), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, TPBi (1,3,5-tri (1-phenyl-1H-benzo[d]imidazol-2-yl)phenyl), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tertbutylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (berylliumbis(benzoquinolin-10-olate), AND (9,10-di(naphthalene-2-yl) anthracene), BmPyPhB (1,3-bis[3,5-di(pyridin-3-yl)phenyl]benzene), or any combination thereof, but is not limited thereto.

The hole auxiliary layer 50 may be between the anode 20 and the photoelectric conversion layer 30, and for example, one surface of the hole auxiliary layer 50 may be in contact with the anode 20, and the other surface (e.g., opposite surface) of the hole auxiliary layer 50 may be in contact with the photoelectric conversion layer 30. The hole auxiliary layer 50 may effectively increase the extraction of holes moving from the photoelectric conversion layer 30 to the anode 20 or may effectively reduce, minimize, or prevent reverse movement of electrons from the anode 20 to the photoelectric conversion layer 30, thereby improving the image sensing performance and/or efficiency (e.g., sensitivity) of the sensor 100. As a result, the sensor 100 may have improved photoelectric conversion performance and/or power consumption efficiency, for example being configured to perform photoelectric conversion of incident light with reduced power consumption without compromising the photoelectric conversion performance of the sensor 100.

The hole auxiliary layer 50 may include, for example, organic materials, inorganic materials, and/or organic and inorganic materials. The hole auxiliary layer 50 may be made of a phthalocyanine compound such as copper phthalocyanine; an aromatic amine compound such as DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′4″-tris(N,N-diphenylamino)triphenylamine), or 2-TNATA (4,4′,4″-tris {N, -(2-naphthyl)-N-phenylamino}-triphenylamine); (poly(3,4-PEDOT/PSS ethylenedioxythiophene)/poly(4-styrenesulfonate)); PANI/DBSA (polyaniline/dodecylbenzenesulfonic acid); PANI/CSA (polyaniline/Camphor sulfonic acid); PANI/PSS (polyaniline/poly(4-styrenesulfonate)); NPB(N,N′-di(naphthalene−1-yl)-N,N′-diphenylbenzidine); polyetherketone (TPAPEK) containing triphenylamine; 4-isopropyl-4′-methyldiphenyliodonium[tetrakis(pentafluorophenyl) borate]; HAT-CN (dipyrazino[2,3-f: 2′,3′-h]quinoxaline-2,3,6,7,10,11-hexacarbonitrile); a carbazole-based derivative such as N-phenylcarbazole or polyvinylcarbazole; a fluorine-based derivative; a triphenylamine-based derivative such as TPD (N,N′-bis(3-methylphenyl)-N,N′-diphenyl-[1,1-biphenyl]-4,4′-diamine) or TCTA (4,4′,4″-tris(N-carbazolyl)triphenylamine); TAPC (4,4′-cyclohexylidene bis[N,N-bis(4-methylphenyl)benzenamine]); HMTPD (4,4′-bis[N,N′-(3-tolyl)amino]-3,3′-dimethylbiphenyl); mCP (1,3-bis(N-carbazolyl)benzene); or any combination thereof, but is not limited thereto.

The electron auxiliary layer 40 and the hole auxiliary layer 50 may each have one or more layers. One or more of the electron auxiliary layer 40 or the hole auxiliary layer 50 may be omitted.

Hereinafter, another example of a sensor according to some example embodiments will be described.

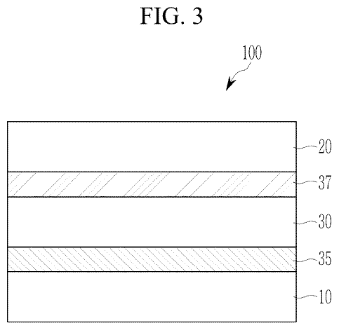

FIG. 3 is a cross-sectional view showing a sensor according to some example embodiments.

Referring to FIG. 3, the sensor 100 according to some example embodiments includes a cathode 10, an anode 20, a photoelectric conversion layer 30, and a first organic auxiliary layer 35, as described above. The description of the cathode 10, the anode 20, the photoelectric conversion layer 30, and the first organic auxiliary layer 35 is the same as described above.

However, unlike some example embodiments, including the example embodiments shown in FIGS. 1 and 2, the sensor 100 according to some example embodiments, including the example embodiments shown in FIG. 3, further includes a second organic auxiliary layer 37.

The second organic auxiliary layer 37 may be between the anode 20 and the photoelectric conversion layer 30, for example, one surface (e.g., the lower surface) of the second organic auxiliary layer 37 may be in contact with the photoelectric conversion layer 30. That is, the first organic auxiliary layer 35, the photoelectric conversion layer 30, and the second organic auxiliary layer 37 may be sequentially stacked in contact with each other (e.g., such that the photoelectric conversion layer is directly between the first organic auxiliary layer and the second organic auxiliary layer 37).

The second organic auxiliary layer 37 may include a singlet fission material, and the singlet fission material may be an organic absorbing material exhibiting a phenomenon in which a singlet exciton generated by absorbing one photon is divided into two triplet excitons, and may be an organic absorbing material satisfying the above-described Relation Formula 1.

The singlet fission material included in the second organic auxiliary layer 37 may be different from the singlet fission material included in the first organic auxiliary layer 35, and may be different from the p-type semiconductor and the n-type semiconductor included in the photoelectric conversion layer 30. For example, the first organic auxiliary layer 35 may include a first singlet fission material and the second organic auxiliary layer 37 may include a second singlet fission material, where the second singlet fission material is different from the first singlet fission material.

The singlet fission material in the second organic auxiliary layer 37 (also referred to herein interchangeably as a second singlet fission material) may be configured to absorb light of at least one spectrum of a red wavelength spectrum, a green wavelength spectrum, a blue wavelength spectrum, or an infrared wavelength spectrum. For example, the singlet fission material included in the second organic auxiliary layer 37 may have an overlapped absorption spectrum with that of the p-type semiconductor and/or the n-type semiconductor of the photoelectric conversion layer 30 and that of the singlet fission material (e.g., first singlet fission material) included in the first organic auxiliary layer 35. For example, in example embodiments where the p-type semiconductor and/or the n-type semiconductor, and the singlet fission material included in the first organic auxiliary layer 35 may be one or more materials configured to selectively absorb light of a first wavelength spectrum selected from a red wavelength spectrum, a green wavelength spectrum, a blue wavelength spectrum, and an infrared wavelength spectrum, the singlet fission material included in the second organic auxiliary layer 37 may be a light-absorbing material configured to absorb light of the first wavelength spectrum.

For example, the first wavelength spectrum may be a green wavelength spectrum, and accordingly, the p-type semiconductor and/or the n-type semiconductor, the singlet fission material included in the first organic auxiliary layer 35, and singlet fission material included in the second organic auxiliary layer 37 may each be an organic absorbing material configured to selectively absorb light in the green wavelength spectrum, and this common absorption wavelength spectrum may correspond to the sensing wavelength of the sensor 100. For example, the wavelength (λ_{max, EQE}) exhibiting the maximum external quantum efficiency of the sensor 100 and the wavelength (λ_{max,IQE}) exhibiting the maximum internal quantum efficiency of the sensor 100 may each belong to the green wavelength spectrum, for example, about 510 nm to about 580 nm, about 520 nm to about 570 nm, about 520 nm to about 560 nm, or about 525 nm to about 550 nm.

The singlet fission material may have an energy level at which the holes generated from the amplified excitons described above and the excitons generated from the photoelectric conversion layer 30 are easily able to move toward the anode 20.

For example, the singlet fission material included in the second organic auxiliary layer 37 may have an equal or shallow HOMO energy level, compared with that of the p-type semiconductor included in the photoelectric conversion layer 30.

For example, the HOMO energy level of the singlet fission material included in the second organic auxiliary layer 37 may be between the HOMO energy level of the p-type semiconductor included in the photoelectric conversion layer 30 and a work function of the anode 20. In other words, the HOMO energy level of the p-type semiconductor included in the photoelectric conversion layer 30, the HOMO energy level of the singlet fission material included in the second organic auxiliary layer 37, and the work function of the anode 20 may have cascading energy levels.

For example, the HOMO energy level of the p-type semiconductor included in the photoelectric conversion layer 30 and the HOMO energy level of the singlet fission material included in the second organic auxiliary layer 37 may have a difference (absolute value reference) of greater than or equal to about 0 eV and less than about 1.0 eV and within the range, about 0 eV to about 0.8 eV, about 0 eV to about 0.7 eV, about 0 eV to about 0.5 eV, about 0 eV to about 0.3 eV, or about 0 eV to about 0.2 eV.

The singlet fission material included in the second organic auxiliary layer 37 is not particularly limited as long as it is an organic material that satisfies the aforementioned Relation Formula 1 and energy levels thereof, and may be, for example, a monomer, dimer, or polymer.

The singlet fission material included in the second organic auxiliary layer 37 may include for example polyacene, polyene, rubrene, any derivative thereof, or any combination thereof, but is not limited thereto.

The polyacene may be selected from, for example, anthracene, tetracene, pentacene, hexacene, heptacene, phenacene, and any derivative thereof. For example, the polyacene or the derivative thereof may be represented by Chemical Formula 2.

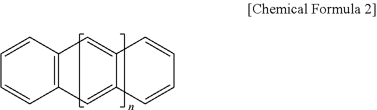

In Chemical Formula 2,
n may be an integer from 1 to 20, and
at least one hydrogen in at least one benzene ring of Chemical Formula 2 may be present (e.g., may independently exist) or may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof. For example, at least one hydrogen of at least one benzene ring of Chemical Formula 2 may each independently exist or may be replaced by deuterium, a halogen, a cyano group, a hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

For example, the polyacene derivative may be an aromatic compound in which at least one hydrogen of polyacene is replaced by a dithienyl group, triisopropylsilyl (TIPS), phenyl group, butyl group, etc. Specific examples may include dithienyl tetracene, TIPS-tetracene, dibithienyl tetracene, diphenyl tetracene, TIPS-pentacene, diphenyl pentacene, dibiphenyl pentacene, dithienyl pentacene, dibithienyl pentacene, etc., but are limited thereto.

The polyene may include butadiene, butadienol, butadienone, hexatriene, hexatrienol, hexatrienone, octatetraene, octatetraenol, octatetraenone, dodecadiene, dodecadienol, undecadienol, undecadienol, tridecadiene, tridedicaene, tridecadienol, tridecadienone, any derivative thereof, or any combination thereof. Herein, in the polyene derivative, at least one hydrogen present in the polyene chain may be present (e.g., may independently exist) or may be replaced by deuterium, a halogen, cyano group, hydroxy group, a C1 to C30 alkyl group, a C2 to C30 alkenyl group, a C2 to C30 alkynyl group, a C1 to C30 alkoxy group, a C3 to C30 cycloalkyl group, a C6 to C30 aryl group, a C2 to C30 heterocycloalkyl group, a C2 to C30 heteroaryl group, a silyl group, or any combination thereof.

The thicknesses of the second organic auxiliary layer 37 may be the same as or thinner than the thickness of the photoelectric conversion layer 30, and may be, for example, about 1 nm to about 500 nm, and within the above range, about 2 nm to about 300 nm, about 5 nm to about 200 nm, about 5 nm to about 100 nm, about 10 nm to about 80 nm, or about 10 nm to about 50 nm.

The sensor 100 according to some example embodiments, including the example embodiments shown in FIG. 3, may include the first and second organic auxiliary layers 35 and 37 on both sides (e.g., opposite sides) of the photoelectric conversion layer 30 to more effectively generate the amplified exciton, and at the same time, electron transfer characteristics and hole transfer characteristics are also good, thereby implementing a sensor 100 exhibiting improved external quantum efficiency (EQE) and internal quantum efficiency (IQE). As a result, the sensor 100 may have improved photoelectric conversion performance and/or power consumption efficiency, for example being configured to perform photoelectric conversion of incident light with reduced power consumption without compromising the photoelectric conversion performance of the sensor 100.

Hereinafter, another example of a sensor according to some example embodiments will be described.

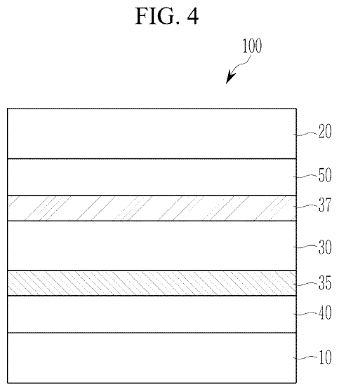

FIG. 4 is a cross-sectional view showing a sensor according to some example embodiments.

Referring to FIG. 4, the sensor 100 according to some example embodiments, like the aforementioned example embodiments shown in FIG. 3, includes a cathode 10, an anode 20, a photoelectric conversion layer 30, a first organic auxiliary layer 35, and a second organic auxiliary layer 37. Descriptions of the cathode 10, the anode 20, the photoelectric conversion layer 30, and the first and second organic auxiliary layers 35 and 37 are as described above referring to FIG. 3.

However, unlike some example embodiments, including the aforementioned example embodiments shown in FIG. 3, the sensor 100 according to some example embodiments, including the example embodiments shown in FIG. 4, further includes electron auxiliary layer 40 and hole auxiliary layer 50.

The electron auxiliary layer 40 may be between the cathode 10 and the first organic auxiliary layer 35, for example, one surface of the electron auxiliary layer 40 may be in contact with the cathode 10, and the other surface (e.g., opposite surface) of the electron auxiliary layer 40 may be in contact with the first organic auxiliary layer 35. The electron auxiliary layer 40 may effectively increase the extraction of electrons moving from the photoelectric conversion layer 30 to the cathode 10 through the first organic auxiliary layer 35 and/or may effectively reduce, minimize, or prevent reverse movement of holes from the cathode 10 to the photoelectric conversion layer 30 through the first organic auxiliary layer 35, thereby improving the image sensing performance and/or efficiency (e.g., sensitivity) of the sensor 100. As a result, the sensor 100 may have improved photoelectric conversion performance and/or power consumption efficiency, for example being configured to perform photoelectric conversion of incident light with reduced power consumption without compromising the photoelectric conversion performance of the sensor 100.

The hole auxiliary layer 50 may be between the anode 20 and the second organic auxiliary layer 37, and for example, one surface of the hole auxiliary layer 50 may be in contact with the anode 20, and the other surface (e.g., opposite surface) of the hole auxiliary layer 50 may be in contact with the second organic auxiliary layer 37. The hole auxiliary layer 50 may effectively increase the extraction of holes moving from the photoelectric conversion layer 30 to the anode 20 through the second organic auxiliary layer 37 or may effectively reduce, minimize, or prevent reverse movement of electrons from the anode 20 to the photoelectric conversion layer 30 through the second organic auxiliary layer 37, thereby improving the image sensing performance and/or efficiency (e.g., sensitivity) of the sensor 100. As a result, the sensor 100 may have improved photoelectric conversion performance and/or power consumption efficiency, for example being configured to perform photoelectric conversion of incident light with reduced power consumption without compromising the photoelectric conversion performance of the sensor 100.

For example, the LUMO energy level of the hole auxiliary layer 50 may be shallower than the work function of the anode 20 and the LUMO energy level of the n-type semiconductor of the photoelectric conversion layer 30, respectively (e.g., may be shallower than each of the work function of the anode 20 and the LUMO energy level of the n-type semiconductor of the photoelectric conversion layer 30), and may be additionally shallower than the LUMO energy level of the singlet fission material of the second organic auxiliary layer 37. For example, the LUMO energy level of the hole auxiliary layer 50 may be shallower than the work function of the anode 20 and the LUMO energy level of the n-type semiconductor of the photoelectric conversion layer 30, respectively, in the range of about 0 to about 3.5 eV, about 0.2 eV to about 3.2 eV, about 0.4 eV to about 3.0 eV, or about 0.5 eV to about 2.9 eV. Accordingly, it is possible to effectively block the reverse movement of electrons from the anode 20 to the photoelectric conversion layer 30 through the second organic auxiliary layer 37.

The electron auxiliary layer 40 and the hole auxiliary layer 50 may each have one or more layers. One or more of the electron auxiliary layer 40 or the hole auxiliary layer 50 may be omitted.

The aforementioned sensor 100 may be applied to, for example, an image sensor. As described above, the sensor 100 may exhibit high efficiency (e.g., improved photoelectric conversion performance and/or power consumption efficiency), and thus it may be effectively applied to image sensors used in low-illumination environments and/or image sensors that require high efficiency.

Hereinafter, an image sensor to which the aforementioned sensor 100 is applied will be described with reference to the drawings. Here, a CMOS image sensor will be described as an image sensor according to some example embodiments.

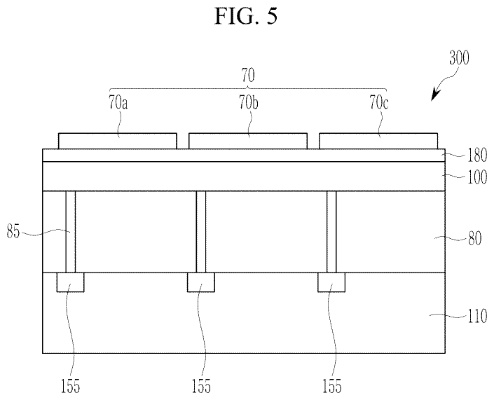

FIG. 5 is a cross-sectional view showing an image sensor according to some example embodiments.

Referring to FIG. 5, an example of the image sensor 300 according to some example embodiments includes a substrate 110, an insulation layer 80, a sensor 100, and a color filter layer 70.

The substrate 110 may be a semiconductor substrate, for example, a silicon substrate or a compound semiconductor substrate. A transmission transistor (not shown) and a charge storage 155 may be integrated for each pixel on the substrate 110, and each charge storage 155 is electrically connected to the sensor 100 of each pixel.

Metal wires (not shown) and pads (not shown) are formed on the front or rear side of the substrate 110. In order to decrease signal delay, the metal wire and pad may be made of a metal having low resistivity, for example, aluminum (AI), copper (Cu), silver (Ag), molybdenum (Mo), nickel (Ni), an alloy thereof, or any combination thereof, but is not limited thereto.

The insulation layer 80 is formed on the substrate 110. The insulation layer 80 may be made of an inorganic insulating material such as a silicon oxide and/or a silicon nitride, or a low dielectric constant (low K) material such as SiC, SiCOH, SiCO, and/or SiOF. The insulation layer 80 has a trench 85 exposing the charge storage 155. The trench 85 may be filled with fillers.

The aforementioned sensor 100 is formed on the insulation layer 80. The sensor 100 may have one of the structures shown in FIGS. 1 to 4, and the detailed description is as described above. One of the cathode 10 or the anode 20 of the sensor 100 may be a light-receiving electrode (or incident electrode) disposed on the side receiving light (e.g., the light incident side, which may be the side closest to the color filter layer 70), and the other of the cathode 10 or the anode 20 of the sensor 100 may be electrically connected to the charge storage 155. For example, the cathode 10 of the sensor 100 may be a light-receiving electrode, and the anode 20 of the sensor 100 may be electrically connected to the charge storage 155. For example, the anode 20 of the sensor 100 may be a light-receiving electrode and the cathode 10 of the sensor 100 may be electrically connected to the charge storage 155.

A color filter layer 70 is formed on the sensor 100. The color filter layer 70 may include a plurality of color filters configured to selectively transmit one or two of the red wavelength spectrum, the green wavelength spectrum, and/or the blue wavelength spectrum, and may include, for example, a first color filter 70a configured to selectively transmit light including a red wavelength spectrum, a second color filter 70b configured to selectively transmit light including a blue wavelength spectrum, and a third color filter 70c configured to selectively transmit light including a green wavelength spectrum. For example, the first color filter 70a may be a red filter, a magenta filter, and/or a yellow filter, for example, the second color filter 70b may be a blue filter, a cyan filter, and/or a magenta filter, and for example, the third color filter 70c may be a green filter, a cyan filter, and/or a yellow filter, and the first, second, and third color filters 70a, 70b, and 70c may be different from each other. The color filter layer 70 may be omitted.

A passivation film 180 is formed between the sensor 100 and the color filter layer 70. The passivation film 180 may be an oxide film, a nitride film, a double layer of an oxide film and a nitride film, or the like. The passivation film 180 may be omitted.

Focusing lens (not shown) may be further formed on the color filter layer 70. The focusing lens may control a direction of incident light and gather the light in one region. The focusing lens may have a shape of, for example, a cylinder or a hemisphere, but is not limited thereto.

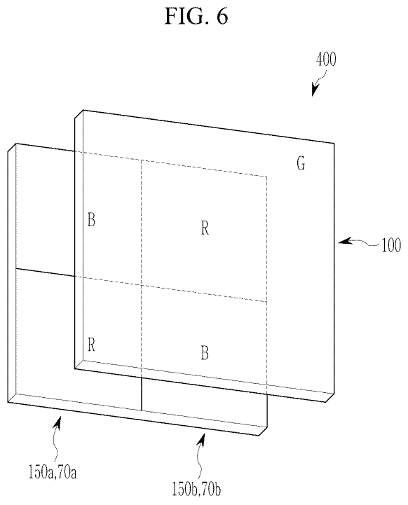

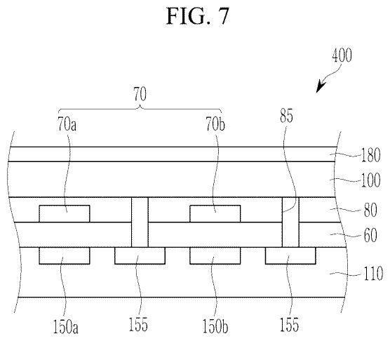

FIG. 6 is a plan view showing an image sensor according to some example embodiments, and FIG. 7 is a cross-sectional view showing the image sensor of FIG. 6 according to some example embodiments.

Referring to FIGS. 6 and 7, an image sensor 400 according to some example embodiments includes a substrate 110 integrated with photo-sensing elements 150a and 150b, a transmission transistor (not shown), and a charge storage 155, a lower insulation layer 60, a color filter layer 70, an upper insulation layer 80, and the aforementioned sensor 100.

The substrate 110 may be, for example, a silicon substrate or a compound semiconductor substrate, and the photo-sensing elements 150a and 150b, the transmission transistor (not shown), and the charge storage 155 are integrated therein. The photo-sensing elements 150a and 150b may be photodiodes.

The photo-sensing elements 150a, and 150b, the transmission transistor, and/or the charge storage 155 may be integrated (e.g., included within a volume space defined by outermost surfaces of the substrate 110) for each pixel. The photo-sensing element 150a may be configured to sense the light passing through the sensor 100 and the first color filter 70a, and the photo-sensing element 150b may sense light that has passed through the sensor 100 and the second color filter 70b. The charge storage 155 may be electrically connected to the photo-sensing elements 150a and 150b or the sensor 100.

Metal wires (not shown) and pads (not shown) are formed on the front or back side of the substrate 110. In order to decrease signal delay, the metal wire and pad may be made of a metal having low resistivity, for example, aluminum (AI), copper (Cu), silver (Ag), molybdenum (Mo), nickel (Ni), an alloy thereof, or any combination thereof, but is not limited thereto. The lower insulation layer 60 is formed on the substrate 110. The lower insulation layer 60 may be made of an inorganic insulating material such as a silicon oxide and/or a silicon nitride, or a low dielectric constant (low K) material such as SiC, SiCOH, SiCO, and SiOF. The lower insulation layer 60 has a trench exposing the charge storage 155 (e.g., a lower portion of trench 85). The trench may be filled with fillers.

A color filter layer 70 is formed on the lower insulation layer 60. The color filter layer 70 includes a plurality of color filters 70a and 70b configured to selectively transmit light in the wavelength spectrum to be sensed by the photo-sensing elements 150a and 150b. The color filter 70a may be overlapped with the photo-sensing element 150a along the thickness direction of the substrate 110 (e.g., a direction extending perpendicular to an in-plane direction of the substrate 110), and the photo-sensing element 150a may sense light that has passed through the color filter 70a. The color filter 70b may be overlapped with the photo-sensing element 150b along the thickness direction of the substrate 110, and the photo-sensing element 150b may be configured to sense light that has passed through the color filter 70b.

The color filters 70a and 70b may be configured to selectively transmit one or two of the red wavelength spectrum, the green wavelength spectrum, or the blue wavelength spectrum. The wavelength spectrum selectively transmitted by the color filters 70a and 70b may be different from the aforementioned first wavelength spectrum selectively absorbed by the photoelectric conversion layer 30 of the sensor 100. For example, the first color filter 70a may be a red filter, a magenta filter, and/or a yellow filter, the second color filter 70b may be a blue filter, a cyan filter, and/or a magenta filter, and the first and second color filters 70a and 70b may be different from each other.

The upper insulation layer 80 is formed on the color filter layer 70. The upper insulation layer 80 may remove a step difference caused by the color filter layer 70 and planarize it. The upper insulation layer 80 and the lower insulation layer 60 have a contact (not shown) exposing the pad and a trench 85 exposing the charge storage 155.

The aforementioned sensor 100 is formed on the upper insulation layer 80. The sensor 100 may have one of the structures shown in FIGS. 1 to 4, and the detailed description is as described above.

One of the cathode 10 or the anode 20 of the sensor 100 may be a light-receiving electrode disposed on the side that receives the light (e.g., incident light), and the other of the cathode 10 or the anode 20 of the sensor 100 may be electrically connected to the charge storage 155. For example, the cathode 10 of the sensor 100 may be a light-receiving electrode, and the anode 20 of the sensor 100 may be electrically connected to the charge storage 155. For example, the anode 20 of the sensor 100 may be a light-receiving electrode and the cathode 10 of the sensor 100 may be electrically connected to the charge storage 155.

As described above, the sensor 100 may be configured to selectively photoelectrically convert light of a first wavelength spectrum selected from the red wavelength spectrum, green wavelength spectrum, blue wavelength spectrum, and infrared wavelength spectrum. The first wavelength spectrum may be different from the wavelength spectrum selectively transmitted by the first and second color filters 70a and 70b. For example, the first wavelength spectrum may be a green wavelength spectrum, the color filter 70a may be configured to selectively transmit light in the red wavelength spectrum, and the color filter 70b may be configured to selectively transmit light in the blue wavelength spectrum. The photoelectric conversion layer 30 of the sensor 100 may be configured to selectively absorb and convert light of the first wavelength spectrum (for example, the green wavelength spectrum), and the singlet fission material of the first and second organic auxiliary layers 35 and 37 also may be configured to absorb light of the first wavelength spectrum (e.g., green wavelength spectrum) to generate amplified excitons.

A passivation film 180 and a focusing lens (not shown) may be further formed on the sensor 100.

As described above, by having a stacked structure of a sensor 100 configured to selectively photoelectrically convert light in the first wavelength spectrum and photo-sensing elements 150a and 150b configured to sense light other than the first wavelength spectrum, the size of the image sensor may be reduced, realizing a highly integrated image sensor.

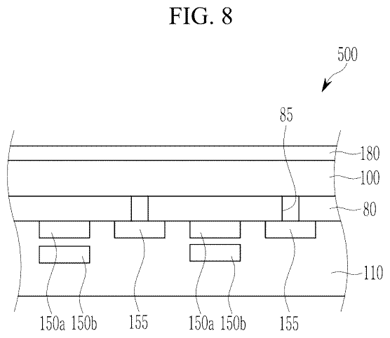

FIG. 8 is a cross-sectional view showing the image sensor of FIG. 6 according to some example embodiments.

Referring to FIG. 8, like some example embodiments, including the aforementioned example embodiments shown in at least FIG. 7, the image sensor 500 according to some example embodiments, including the example embodiments shown in FIG. 8 includes a substrate 110 in which photo-sensing elements 150a and 150b, a transfer transistor (not shown) and a charge storage 155 are integrated, and an upper insulation layer 80, a sensor 100 and a passivation film 180.

However, in the image sensor 500 according to some example embodiments, including the example embodiments shown in FIG. 8, unlike some example embodiments, including the example embodiments shown in FIG. 7, the photo-sensing elements 150a and 150b are stacked in the vertical direction (e.g., a direction extending perpendicular to the in-plane direction of the substrate 110) and the color filter layer 70 is omitted. The photo-sensing elements 150a and 150b may be configured to selectively absorb light in each wavelength region depending on the stacking depth. The sensor 100 may have one of the structures shown in FIGS. 1 to 4, and the detailed description is the same as described above. One of the cathode 10 or the anode 20 of the sensor 100 may be a light-receiving electrode disposed on the side that receives the light, and the cathode 10 and the anode 20 of the sensor 100 may be a light-receiving electrode and the other one may be electrically connected to the charge storage 155. For example, the cathode 10 of the sensor 100 may be a light-receiving electrode, and the anode 20 of the sensor 100 may be electrically connected to the charge storage 155. For example, the anode 20 of the sensor 100 may be a light-receiving electrode and the cathode 10 of the sensor 100 may be electrically connected to the charge storage 155.

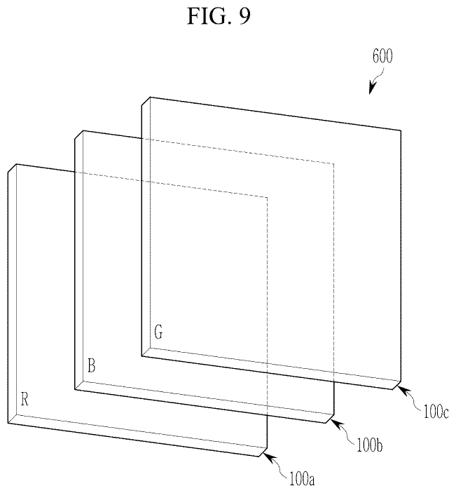

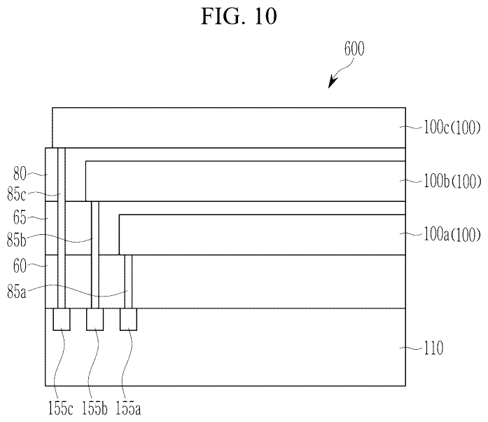

FIG. 9 is a plan view showing an image sensor according to some example embodiments, and FIG. 10 is a cross-sectional view showing the image sensor of FIG. 9 according to some example embodiments.

The image sensor 600 according to some example embodiments, including the example embodiments shown in FIGS. 9-10, includes a first sensor 100a configured to photoelectrically convert light of a first wavelength spectrum selected from a red wavelength spectrum, a green wavelength spectrum, and a blue wavelength spectrum, a second sensor 100b configured to photoelectrically convert light of a second wavelength spectrum selected from the red wavelength spectrum, the green wavelength spectrum, and the blue wavelength spectrum, and a third sensor 100c configured to photoelectrically convert light of a third wavelength spectrum selected from the red wavelength spectrum, the green wavelength spectrum, and the blue wavelength spectrum, and the first sensor 100a, the second sensor 100b, and the third sensor 100c are stacked in the thickness direction of the substrate 110. Herein, the first wavelength spectrum, the second wavelength spectrum, and the third wavelength spectrum may be different from each other.

The image sensor 600 according to some example embodiments, including the example embodiments shown in FIGS. 9-10, includes a substrate 110, a lower insulation layer 60, an intermediate insulation layer 65, an upper insulation layer 80, a first sensor 100a, a second sensor 100b, and a third sensor 100c.

The substrate 110 may be a semiconductor substrate, for example, a silicon substrate or a compound semiconductor substrate. On the substrate 110, a transmission transistor (not shown) and charge storages 155a, 155b, and 155c are integrated for each pixel. Metal wires (not shown) and pads (not shown) are formed on the front or back of the substrate 110, and a lower insulation layer 60 is formed on the substrate 110.

The first sensor 100a, the second sensor 100b, and the third sensor 100c are sequentially formed on the lower insulation layer 60. The first, second, and third sensors 100a, 100b, and 100c may be each the aforementioned sensor 100.

The first, second, and third sensors 100a, 100b, and 100c may each independently have one of the structures shown in FIGS. 1 to 4, and detailed descriptions are as described above. One of the cathode 10 or the anode 20 of the first, second, and third sensors 100a, 100b, and 100c may be a light-receiving electrode disposed on the side receiving light, and the other of the cathode 10 or the anode 20 of the first, second, and third sensors 100a, 100b, and 100c may be electrically connected to the charge storages 155a, 155b, and 155c.

The photoelectric conversion layer 30 of the first sensor 100a may be configured to selectively absorb light of a first wavelength spectrum selected from the red wavelength spectrum, the green wavelength spectrum, and the blue wavelength spectrum and photoelectrically convert the absorbed light. The first wavelength spectrum may be, for example, a red wavelength spectrum, and the first sensor 100a may be a red sensor configured to selectively absorb light in the red wavelength spectrum and convert the absorbed light into photoelectricity.

An intermediate insulation layer 65 is formed on the first sensor 100a, and a second sensor 100b is formed on the intermediate insulation layer 65. The intermediate insulation layer 65 may be made of an inorganic insulating material such as a silicon oxide and/or a silicon nitride, or a low dielectric constant (low K) material such as SiC, SiCOH, SiCO, and SiOF.

The photoelectric conversion layer 30 of the second sensor 100b may be configured to selectively absorb light of a second wavelength spectrum selected from the red wavelength spectrum, the green wavelength spectrum, and the blue wavelength spectrum and photoelectrically convert the absorbed light. The second wavelength spectrum may be, for example, a green wavelength spectrum, and the second sensor 100b may be a green sensor configured to selectively absorb light in the green wavelength spectrum and convert the absorbed light into photoelectricity.

An upper insulation layer 80 is formed on the second sensor 100b. The lower insulation layer 60, intermediate insulation layer 65, and upper insulation layer 80 may have a plurality of trenches 85a, 85b, and 85c exposing charge storages 155a, 155b, and 155c. The third sensor 100c is formed on the upper insulation layer 80.

The photoelectric conversion layer 30 of the third sensor 100c may be configured to selectively absorb light of a third wavelength spectrum selected from the red wavelength spectrum, the green wavelength spectrum, and the blue wavelength spectrum and photoelectrically convert the absorbed light. The third wavelength spectrum may be, for example, a blue wavelength spectrum, and the third sensor 100c may be a blue sensor configured to selectively absorb light in the blue wavelength spectrum and photoelectrically convert the absorbed light.

A focusing lens (not shown) may be further formed on the third sensor 100c.

In the drawing, a structure in which the first sensor 100a, the second sensor 100b, and the third sensor 100c are sequentially stacked is shown, but the stacking order is not limited to this and may vary.

As described above, the first sensor 100a, the second sensor 100b, and the third sensor 100c, which absorb light of different wavelength spectra and convert it into photoelectricity, have a stacked structure to further reduce the size of the image sensor and implement a high integration image sensor.

The aforementioned sensor 100 may be for example applied to a display panel. The sensor 100 may be embedded in a display panel as an in-cell type, and the display panel may perform both a display function and a recognition function (e.g., a biometric recognition function).

Hereinafter, an example of a display panel to which the aforementioned sensor 100 is applied will be described with reference to the drawings.

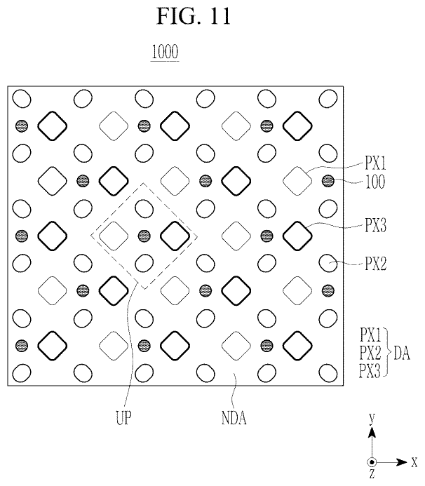

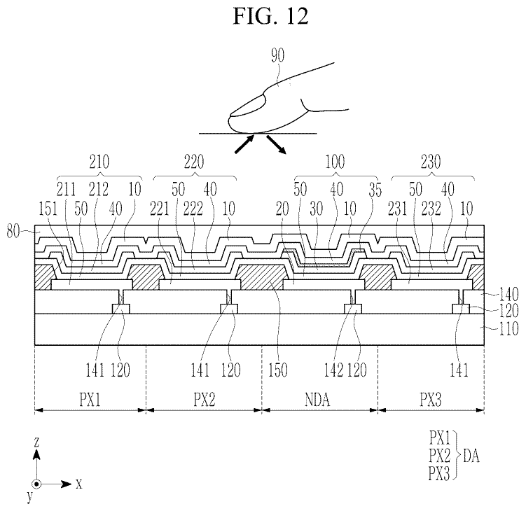

FIG. 11 is a plan view showing a sensor-embedded display panel according to some example embodiments, and FIG. 12 is a cross-sectional view showing a sensor-embedded display panel according to some example embodiments.

Referring to FIGS. 11 and 12, the display panel 1000 according to some example embodiments includes a plurality of subpixels PX1, PX2, and PX3 that display different colors. The plurality of subpixels PXs may be configured to display at least three primary colors, for example, a first subpixel PX1, a second subpixel PX2, and a third subpixel PX3 displaying different first color, second color, and third color selected from red, green, and blue. For example, the first color, the second color, and the third color may be red, green, and blue, respectively. The first subpixel PX1 may be a red subpixel displaying red, the second subpixel PX2 may be a green subpixel displaying green, and the third subpixel PX3 may be a blue subpixel displaying blue. However, the present inventive concepts are not limited thereto, and an auxiliary subpixel (not shown) such as a white subpixel may be further included.

The plurality of subpixels PXs including the first subpixel PX1, the second subpixel PX2, and the third subpixel PX3 may constitute (e.g., may define) one unit pixel UP to be arranged repeatedly along the row and/or column. In FIG. 11, a structure including one first subpixel PX1, two second subpixels PX2, and one third subpixel PX3 in the unit pixel UP is illustrated, but the present inventive concepts are not limited thereto. At least one first subpixel PX1, at least one second subpixel PX2, and at least one third subpixel PX3 may be included in the unit pixel UP. In the drawing, as an example, an arrangement of a Pentile type is illustrated, but the present inventive concepts are not limited thereto. The subpixels PXs may be arranged variously. An area occupied by the plurality of subpixels PXs and displaying colors by the plurality of subpixels PXs may be a display area DA displaying an image. For example, the area (e.g., in the xy plane) of the subpixels PX may collectively define the display area DA that is configured to display an image thereon (e.g., configured to display one or more colors). A portion of the area (e.g., in the xy plane) of the sensor-embedded display panel 1000 that excludes the display area DA (e.g., portions of the area of the sensor-embedded display panel 1000 that are between adjacent subpixels PX in the xy direction, xy plane, etc.) may be a non-display area NDA that is configured to not display an image thereon (e.g., configured to not display any color).

Each of the first subpixel PX1, the second subpixel PX2, and the third subpixel PX3 may include a light emitting element. As an example, the first subpixel PX1 may include a first light emitting element 210 configured to emit light of a wavelength spectrum of a first color, the second subpixel PX2 may include a second light emitting element 220 configured to emit light of a wavelength spectrum of a second color, and the third subpixel PX3 may include a third light emitting element 230 configured to emit light of a wavelength spectrum of a third color. However, the present inventive concepts are not limited thereto, and at least one of the first subpixel PX1, the second subpixel PX2, or the third subpixel PX3 may include a light emitting element configured to emit light of a combination of a first color, a second color, and a third color, that is, light in a white wavelength spectrum, and may display a first color, a second color, or a third color through a color filter (not shown). Herein, the terms “wavelength spectrum” and “wavelength region” may be used interchangeably.

The display panel 1000 according to some example embodiments includes a sensor 100. The sensor 100 may be disposed in a non-display area NDA. The non-display area NDA may be an area other than the display area DA, in which the first subpixel PX1, the second subpixel PX2, the third subpixel PX3, and optionally auxiliary subpixels are not arranged (e.g., a portion of the total area of the sensor-embedded display panel 1000 that excludes the display area DA, excludes the subpixels PX, is between adjacent subpixels PX, etc.). For example, the area (e.g., in the xy plane) of the subpixels PX may collectively define the display area DA that is configured to display an image thereon (e.g., configured to display one or more colors). A portion of the area (e.g., in the xy plane) of the sensor-embedded display panel 1000 that excludes the display area DA (e.g., portions of the area of the sensor-embedded display panel 1000 that are between adjacent subpixels PX in the xy direction, xy plane, etc.) may be a non-display area NDA that is configured to not display an image thereon (e.g., configured to not display any color). The sensor 100 may be disposed between at least two subpixels selected from the first subpixel PX1, the second subpixel PX2, and the third subpixel PX3 (e.g., between at least two subpixels of a first subpixel PX1 of a plurality of first subpixels PX1, a second subpixel PX2 of the plurality of second subpixels PX2, or a third subpixel PX3 of the plurality of third subpixels PX3), and may be disposed in parallel with the first, second, and third light emitting elements 210, 220, and 230 in the display area DA for example in parallel along the in-plane direction of the substrate 110 (e.g., the xy direction as shown), which may be a direction extending parallel to an upper surface of the substrate 110.

The sensor 100 may be an optical type recognition sensor (e.g., a biometric sensor). The sensor 100 may be configured to absorb light generated by reflection of light emitted from at least one of the first, second, or third light emitting elements 210, 220, or 230 disposed in the display area DA, by a recognition target 90 such as a living body, a tool, or a thing (e.g., may be configured to absorb light of a red wavelength spectrum, a green wavelength spectrum, a blue wavelength spectrum, an infrared wavelength spectrum, or any combination thereof), and then may convert it (the absorbed light) into an electrical signal. Herein, the living body may be a finger, a fingerprint, a palm, an iris, a face, and/or a wrist, but is not limited thereto. The sensor 100 may be, for example, a fingerprint sensor, an illumination sensor, an iris sensor, a distance sensor, a blood vessel distribution sensor, and/or a heart rate sensor, but is not limited thereto.

The sensor 100 may be disposed on the same plane as the first, second, and third light emitting elements 210, 220, and 230 on the substrate 110, and may be embedded in the display panel 1000. Restated, the sensor 100 may be in parallel with the first, second, and third light emitting elements 210, 220, and 230 on the substrate 110 along an in-plane direction of the substrate 110. As described herein, the in-plane direction of the substrate 110 may be a direction (e.g., the xy direction as shown) that extends in parallel with at least a portion of the substrate 110, including an upper surface of the substrate 110.

Referring to FIG. 12, the display panel 1000 includes a substrate 110; a thin film transistor 120 on the substrate 110; an insulation layer 140 on the thin film transistor 120; a pixel definition layer 150 on the insulation layer 140; and first, second, and third light emitting elements 210, 220, and 230 and the sensor 100 in a space partitioned by the pixel definition layer 150.

The substrate 110 may be a light transmitting substrate, for example, a glass substrate or a polymer substrate. The polymer substrate may include, for example, polycarbonate, polymethylmethacrylate, polyethyleneterephthalate, polyethylenenaphthalate, polyimide, polyamide, polyamideimide, polyethersulfone, polyorganosiloxane, a styrene-ethylene-butylene-styrene copolymer, polyurethane, polyacrylate, polyolefin, or any combination thereof, but is not limited thereto.

A plurality of thin film transistors 120 are formed on the substrate 110. One or more thin film transistors 120 may be included in each subpixel PX, and may include, for example, at least one switching thin film transistor and/or at least one driving thin film transistor. The substrate 110 on which the thin film transistor 120 is formed may be referred to as a thin film transistor substrate (TFT substrate) or a thin film transistor backplane (TFT backplane).

The insulation layer 140 may cover the substrate 110 and the thin film transistor 120 and may be formed on the whole surface of the substrate 110. The insulation layer 140 may be a planarization layer or a passivation layer, and may include an organic insulating material, an inorganic insulating material, an organic-inorganic insulating material, or any combination thereof. The insulation layer 140 may have a plurality of contact holes 141 for electrically connecting the first, second, and third light emitting elements 210, 220, and 230 and the thin film transistor 120 and a plurality of contact holes 142 for electrically connecting the sensor 100 and the thin film transistor 120. The insulation layer 140 may include an inorganic material, an organic material, an inorganic material, or any combination thereof. The inorganic material may be, for example, silicon oxide, silicon nitride, silicon oxynitride, aluminum oxide, or aluminum nitride, the organic material may be, for example, polyimide, polyamide, polyamideimide, or polyacrylate, and the organic material may be, for example, polyorganosiloxane, or polyorganosilazane.

The pixel definition layer 150 may also be formed on the whole surface of the substrate 110 and may be disposed between adjacent subpixels PXs to partition each subpixel PX. The pixel definition layer 150 may have a plurality of openings 151 disposed in each subpixel PX, and in each opening 151, any one of first, second, and third light emitting elements 210, 220, and 230 and the sensors 100 may be disposed.

The pixel definition layer 150 may include an inorganic material, an organic material, an inorganic material, or any combination thereof. The inorganic material may be, for example, silicon oxide, silicon nitride, silicon oxynitride, aluminum oxide, or aluminum nitride, the organic material may be, for example, polyimide, polyamide, polyamideimide, or polyacrylate, the organic/inorganic material may be, for example, polyorganosiloxane or polyorganosilazane.

The first, second and third light emitting elements 210, 220, and 230 are formed on the substrate 110 (or thin film transistor substrate), and are repeatedly arranged along the in-plane direction (e.g., xy direction) of the substrate 110 to form a light emitting element array. As described above, the first, second, and third light emitting elements 210, 220, and 230 may be included in the first subpixel PX1, the second subpixel PX2, and the third subpixel PX3, respectively. The first, second, and third light emitting elements 210, 220, and 230 may be electrically connected to separate thin film transistors 120 and may be driven independently.

The first, second, and third light emitting elements 210, 220, and 230 may be configured to each independently emit one light of a red wavelength spectrum, a green wavelength spectrum, a blue wavelength spectrum, or any combination thereof. For example, the first light emitting element 210 may be configured to emit light of a red wavelength spectrum, the second light emitting element 220 may be configured to emit light of a green wavelength spectrum, and the third light emitting element 230 may be configured to emit light of a blue wavelength spectrum. Herein, the red wavelength spectrum, the green wavelength spectrum, and the blue wavelength spectrum may have a maximum emission wavelength (Δ_{peak,L}) in a wavelength region of greater than about 600 nm and less than about 750 nm, about 500 nm to about 600 nm, and greater than or equal to about 400 nm and less than about 500 nm, respectively.

The first, second, and third light emitting elements 210, 220, and 230 may be, for example, light emitting diodes, for example organic light emitting diodes (OLEDs) including an organic light emitting material.

The sensor 100 may be formed on the substrate 110 (or the thin film transistor substrate), and may be randomly or regularly arranged along the in-plane direction (e.g., xy direction) of the substrate 110. As described above, the sensor 100 may be disposed in the non-display area NDA, and may be connected to a separate thin film transistor 120 to be independently driven.

The sensor 100 may be configured to absorb light belonging to a wavelength spectrum of the light emitted from at least one of the first, second, and third light emitting elements 210, 220, and 230 and then convert it into an electrical signal. For example, the sensor 100 may be configured to absorb light of a red wavelength spectrum and a green wavelength spectrum, a blue wavelength spectrum, and any combination thereof, and then convert it into an electrical signal and for example, light of a green wavelength spectrum may be absorbed and converted into an electrical signal.

Each of the first, second, and third light emitting elements 210, 220, and 230 and the sensor 100 may include a pixel electrode 211, 221, 231, and 20; a common electrode 10 facing the pixel electrodes 211, 221, 231, and 20 and to which a common voltage is applied; and light emitting layers 212, 222, and 232 or a photoelectric conversion layer 30, a first common auxiliary layer 40, and a second common auxiliary layer 50 between the pixel electrode 211, 221, 231, and 20 and the common electrode 10.

The common electrode 10 of the sensor 100 may be the cathode 10 of the sensor 100 shown in FIGS. 1 to 4, and the pixel electrode 20 of the sensor 100 may be the anode 20 of the sensor 100 shown in FIGS. 1 to 4. The photoelectric conversion layer 30 of the sensor 100 may be the photoelectric conversion layer 30 of the sensor 100 shown in FIGS. 1 to 4. The first common auxiliary layer 40 of the sensor 100 may be the electron auxiliary layer 40 of the sensor 100 shown in FIGS. 2 and 4 and the second common auxiliary layer 50 of the sensor 100 may be the hole auxiliary layer 50 of the sensor 100 shown in FIGS. 2 and 4. The sensor 100 further includes the first organic auxiliary layer 35 between the common electrode 10 and the photoelectric conversion layer 30, and the descriptions of the first organic auxiliary layers 35 is the same as described above.

The first, second, and third light emitting elements 210, 220, and 230 and the sensor 100 may be arranged in parallel along the in-plane direction (e.g., xy direction) of the substrate 110, and may share the common electrode 10, the first common auxiliary layer 40, and the second common auxiliary layer 50 which are formed on the whole surface of the substrate 110.

The common electrode 10 is continuously formed as a single piece of material that extends on the light emitting layers 212, 222, and 232 and the photoelectric conversion layer 30, and is formed substantially on the whole surface of the substrate 110. The common electrode 10 may apply a common voltage to the first, second, and third light emitting elements 210, 220, and 230 and the sensor 100. As shown, the first, second, and third light emitting elements 210, 220, and 230 and the sensor 100 may include separate portions of a single common electrode 10 that is a single piece of material that extends on each of the respective light emitting layers 212, 222, and 232 and the photoelectric conversion layer 30 and between the first, second, and third light emitting elements 210, 220, and 230 and the sensor 100.

The first common auxiliary layer 40 may be between the light emitting layers 212, 222, 232 and the photoelectric conversion layer 30, and the substrate 110, and among them, between the light emitting layers 212, 222, 232 and the photoelectric conversion layer 30, and the common electrodes 10. The first common auxiliary layer 40 may be continuously formed by being connected to each other on the lower portion of the light emitting layers 212, 222, 232 and the photoelectric conversion layer 30 and on the upper portion of the common electrode 10. As shown, the first, second, and third light emitting elements 210, 220, and 230 and the sensor 100 may include separate portions of a single first common auxiliary layer 40 that is a single piece of material that extends on each of the respective light emitting layers 212, 222, and 232 and the photoelectric conversion layer 30 and between the first, second, and third light emitting elements 210, 220, and 230 and the sensor 100. The first common auxiliary layer 40 may be an electron auxiliary layer that facilitates injection and/or movement of electrons from the common electrode 10 to the light emitting layers 212, 222, and 232. The first common auxiliary layer 40 may include an electron transport material.

For example, the LUMO energy level of the first common auxiliary layer 40 (e.g., electron transport material) may be between the LUMO energy level of the light emitting layers 212, 222, and 232 (the LUMO energy level of the organic light emitting material of the light emitting layer) and the work functions of the common electrode 10. The work functions of the common electrode 10, the LUMO energy levels of the first common auxiliary layer 40, and the LUMO energy levels of the light emitting layers 212, 222, and 232 may be sequentially shallowed. For example, the LUMO energy level of the first common auxiliary layer 40 (e.g., electron transport material) may be about 2.9 eV to about 3.3 eV, and may be about 2.9 eV to about 3.2 eV, about 2.9 eV to about 3.1 eV, about 3.0 eV to about 3.2 eV or about 3.0 eV to about 3.1 eV within the above range, but is not limited thereto.

The second common auxiliary layer 50 may be between the light emitting layers 212, 222, 232 and the photoelectric conversion layer 30, and the substrate 110, and among them, between the light emitting layers 212, 222, 232 and the photoelectric conversion layer 30, and the pixel electrodes 211, 221, 231, and 20. The second common auxiliary layer 50 may be continuously formed as a single piece of material that extends on the lower portions of the light emitting layers 212, 222, and 232 and the photoelectric conversion layer 30 and on the upper portions of pixel electrodes 211, 221, 231, and 20. As shown, the first, second, and third light emitting elements 210, 220, and 230 and the sensor 100 may include separate portions of a single second common auxiliary layer 50 that is a single piece of material that extends under each of the respective light emitting layers 212, 222, and 232 and the photoelectric conversion layer 30 and between the first, second, and third light emitting elements 210, 220, and 230 and the sensor 100.

The second common auxiliary layer 50 may be a charge auxiliary layer (e.g., hole auxiliary layer) that facilitates injection and/or movement of charge carriers (e.g., holes) from the pixel electrodes 211, 221, and 231 to the light emitting layers 212, 222, and 232. The second common auxiliary layer 50 may include a charge transport material, for example, a hole transport material. For example, the HOMO energy level of the second common auxiliary layer 50 (e.g., hole transport material) may be between the HOMO energy level of the light emitting layers 212, 222, and 232 (the HOMO energy level of the organic light emitting material of the light emitting layer) and the work functions of the pixel electrodes 211, 221, and 231 (conductor of the pixel electrode). The work functions of the pixel electrodes 211, 221, and 231, the HOMO energy levels of the second common auxiliary layer 50, and the HOMO energy levels of the light emitting layers 212, 222, and 232 may be sequentially deepened. For example, the HOMO energy level of the second common auxiliary layer 50 (e.g., hole transport material) may be about 5.3 eV to about 5.6 eV, and may be about 5.3 eV to about 5.5 eV within the above range, but is not limited thereto.

Each of the first, second, and third light emitting elements 210, 220, and 230 and the sensor 100 includes a separate pixel electrode 211, 221, 231, or 20 facing the common electrode 10. For example, the pixel electrodes 211, 221, 231, and 20 may be an anode, and the common electrode 10 may be a cathode. The pixel electrodes 211, 221, 231, and 20 are separated for each subpixel PX, and are electrically connected to each separate thin film transistor 120 to be independently driven.

The pixel electrodes 211, 221, 231, and 20 may be a light transmitting electrode (a transparent electrode or a semi-transmissive electrode) or a reflective electrode. The light transmitting electrode is the same as described above (e.g., one or more selected from indium tin oxide (ITO), indium zinc oxide (IZO), zinc tin oxide (ZTO), aluminum tin oxide (ATO), and aluminum zinc oxide (AZO)). The reflective electrode may include a reflective layer having a light transmittance of less than or equal to about 5% and/or a reflectance of greater than or equal to about 80%, and the reflective layer may include an optically opaque material. The optically opaque material may include a metal, a metal nitride, or any combination thereof, for example silver (Ag), copper (Cu), aluminum (AI), gold (Au), titanium (Ti), chromium (Cr), nickel (Ni), an alloy thereof, a nitride thereof (e.g., TiN), or any combination thereof, but is not limited thereto. The reflective electrode may be formed of a reflective layer or may have a stacked structure of a reflective layer/transmissive layer or a transmissive layer/reflective layer/transmissive layer, and the reflective layer may be one layer or two or more layers. For example, when the pixel electrodes 211, 221, 231, and 20 are reflective electrodes and the common electrode 10 is a light transmitting electrode, the sensor-embedded display panel 1000 may be a top emission type display panel configured to emit light toward the opposite side of the substrate 110. For example, when the pixel electrodes 211, 221, 231, and 20 and the common electrode 10 are light transmitting electrodes, respectively, the sensor-embedded display panel 1000 may be a both side emission type display panel configured to emit light toward both the substrate 110 and the opposite side of the substrate 110. For example, the pixel electrodes 211, 221, 231, and 20 may be reflective electrodes and the common electrode 10 may be a semi-transmissive electrode. In this case, the sensor-embedded display panel 1000 may have a microcavity structure. In the microcavity structure, reflection may occur repeatedly between the reflective electrode and the semi-transmissive electrode separated by a particular (or, alternatively, predetermined) optical length (e.g., a distance between the semi-transmissive electrode and the reflective electrode) and light of a particular (or, alternatively, predetermined) wavelength spectrum may be enhanced to improve optical properties. For example, among the light emitted from the light emitting layers 212, 222, and 232 of the first, second, and third light emitting elements 210, 220, and 230, light of a particular (or, alternatively, predetermined) wavelength spectrum may be repeatedly reflected between the semi-transmissive electrode and the reflective electrode and then may be modified. Among the modified light, light of a wavelength spectrum corresponding to a resonance wavelength of a microcavity may be enhanced to exhibit amplified light emission characteristics in a narrow wavelength region. Accordingly, the sensor-embedded display panel 1000 may express colors with high color purity.

For example, among the light incident on the sensor 100, light of a particular (or, alternatively, predetermined) wavelength spectrum may be repeatedly reflected between the semi-transmissive electrode and the reflective electrode to be modified. Among the modified light, light having a wavelength spectrum corresponding to the resonance wavelength of a microcavity may be enhanced to exhibit photoelectric conversion characteristics amplified in a narrow wavelength region. Accordingly, the sensor 100 may exhibit high photoelectric conversion characteristics in a narrow wavelength region.

Each of the first, second, and third light emitting elements 210, 220, and 230 includes light emitting layers 212, 222, and 232 between the pixel electrodes 211, 221, and 231 and the common electrode 10. Each of the light emitting layer 212 included in the first light emitting element 210, the light emitting layer 222 included in the second light emitting element 220, and the light emitting layer 232 included in the third light emitting element 230 may be configured to emit light in the same or different wavelength spectra and may be configured to emit light in, for example a red wavelength spectrum, a green wavelength spectrum, a blue wavelength spectrum, or any combination thereof.

For example, when the first light emitting element 210, the second light emitting element 220, and the third light emitting element 230 are a red light emitting element, a green light emitting element, and a blue light emitting element, respectively, the light emitting layer 212 included in the first light emitting element 210 may be a red light emitting layer configured to emit light in a red wavelength spectrum, the light emitting layer 222 included in the second light emitting element 220 may be a green light emitting layer configured to emit light in a green wavelength spectrum, and the light emitting layer 232 included in the third light emitting element 230 may be a blue light emitting layer configured to emit light in a blue wavelength spectrum. Herein, the red wavelength spectrum, the green wavelength spectrum, and the blue wavelength spectrum may have a peak emission wavelength (\peak, L) of greater than about 600 nm and less than about 750 nm, about 500 nm to about 600 nm, and greater than or equal to about 380 nm and less than about 500 nm, respectively.

For example, when at least one of the first light emitting element 210, the second light emitting element 220, or the third light emitting element 230 is a white light emitting element, the light emitting layer of the white light emitting element may be configured to emit light of a full visible light wavelength spectrum, for example, light in a wavelength spectrum of greater than or equal to about 380 nm and less than about 750 nm, about 400 nm to about 700 nm, or about 420 nm to about 700 nm.

The light emitting layers 212, 222, and 232 may include at least one host material and a fluorescent or phosphorescent dopant, and at least one of the at least one host material and the fluorescent or phosphorescent dopant may be an organic light emitting material. The organic light emitting material may include, for example, a low molecular organic light emitting material, for example, a vapor depositable organic light emitting material. The organic light emitting material included in the light emitting layers 212, 222, and 232 is not particularly limited as long as it is an electroluminescent material capable of emitting light of a particular (or, alternatively, predetermined) wavelength spectrum, and may be, for example, perylene; rubrene; 4-(dicyanomethylene)-2-methyl-6-[p-(dimethylamino) styryl]-4H-pyran; coumarin or any derivative thereof; carbazole or any derivative thereof; TPBi (2,2′,2″-(1,3,5-benzinetriyl)-tris(1-phenyl-1-H-benzimidazole); TBADN (2-t-butyl-9,10-di(naphth-2-yl) anthracene); AND (9,10-di(naphthalene-2-yl) anthracene); CBP (4,4′-bis(N-carbazolyl)-1,1′-biphenyl); TCTA (4,4′,4″-tris(carbazol-9-yl)-triphenylamine); TPBi (1,3,5-tris(N-phenylbenzimidazole-2-yl)benzene); TBADN (3-tert-butyl-9,10-di(naphth-2-yl) anthracene); DSA (distyrylarylene); CDBP (4,4′-bis(9-carbazolyl)-2,2′-dimethyl-biphenyl); MADN (2-methyl-9,10-bis(naphthalen-2-yl) anthracene); TCP (1,3,5-tris(carbazol-9-yl)benzene); Alq₃ (tris(8-hydroxyquinolino) lithium); an organometallic compound including Pt, Os, Ti, Zr, Hf, Eu, Tb, Tm, Rh, Ru, Re, Be, Mg, Al, Ca, Mn, Co, Cu, Zn, Ga, Ge, Pd, Ag, and/or Au, any derivative thereof, or any combination thereof, but is not limited thereto.

The organic light emitting material included in the light emitting layers 212, 222, and 232 may be a depositable organic light emitting material that may be vaporized (sublimated) at a particular (or, alternatively, predetermined) temperature to be deposited, and may have a particular (or, alternatively, predetermined) sublimation temperature (Ts). Herein, the sublimation temperature may be a temperature at which a weight loss of 10% relative to the initial weight occurs during thermogravimetric analysis (TGA) at a low pressure of about 10 Pa or less, and may be a deposition temperature during the process or a set temperature of a deposition chamber used in the process.

The sublimation temperature (Ts) of the organic light emitting material included in the light emitting layer 212, 222, and 232 may be less than or equal to about 350° C., and within the above range, less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., or less than or equal to about 250° C., about 100° C. to about 350° C., about 100° C. to about 340° C., about 100° C. to about 330° C., about 100° C. to about 320° C., about 100° C. to about 310° C., about 100° C. to about 300° C., about 100° C. to about 290° C., about 100° C. to about 280° C., about 100° C. to about 270° C., about 100° C. to about 260° C., about 100° C. to about 250° C., about 150° C. to about 350° C., about 150° C. to about 340° C., about 150° C. to about 330° C., about 150° C. to about 320° C., about 150° C. to about 310° C., about 150° C. to about 300° C., about 150° C. to about 290° C., about 150° C. to about 280° C., about 150° C. to about 270° C., about 150° C. to about 260° C., or about 150° C. to about 250° C. When the organic light emitting material has a sublimation temperature within the above range, it may be effectively deposited without substantial decomposition and/or deterioration of the organic light emitting material.

The sensor 100 includes a photoelectric conversion layer 30 between the pixel electrode 20 and the common electrode 10. The photoelectric conversion layer 30 may be between the first common auxiliary layer 40 and the second common auxiliary layer 50. The photoelectric conversion layer 30 is disposed in parallel with the light emitting layers 212, 222, and 232 of the first, second, and third light emitting elements 210, 220, and 230 along the in-plane direction (e.g., xy direction) of the substrate 110. The photoelectric conversion layer 30 and the light emitting layers 212, 222, and 232 may be disposed on the same plane. The description of the photoelectric conversion layer 30 is the same as described above.

The sensor 100 includes the first organic auxiliary layer 35 between the common electrode 10 and the photoelectric conversion layer 30. The first organic auxiliary layers 35, as described above, may include a singlet fission material to absorb light of a particular (or, alternatively, predetermined) wavelength spectrum, which splits from the excited singlet state (S₁) to the triplet state (T₁) to produce (e.g., about twice) amplified excitons, wherein the amplified excitons are combined with the excitons produced in the photoelectric conversion layer 30 to increase charges and thus increase efficiency of the sensor. Accordingly, external quantum efficiency (EQE) and/or internal quantum efficiency (IQE) of the sensor 100 may be theoretically greater than 100%. The first organic auxiliary layer 35 may be the same as described above.

Although FIG. 12 illustrates an example in which the sensor 100 shown in FIG. 2 is included as an example, the sensor 100 shown in FIG. 4 may be included without being limited thereto.

The aforementioned display panel 1000 may be applied to electronic devices such as various display devices. Electronic devices such as display devices may be applied to, for example, mobile phones, video phones, smart phones, mobile phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but are not limited thereto.

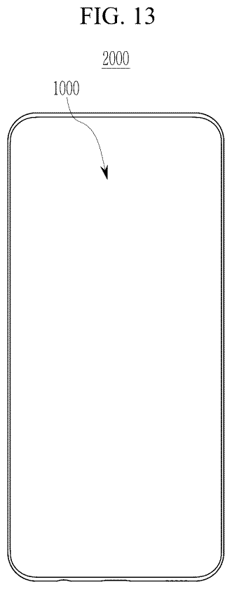

FIG. 13 is a schematic view showing a smart phone as an electronic device according to some example embodiments.

Referring to FIG. 13, the electronic device 2000 may include the aforementioned display panel 1000, and the sensor 100 on the whole or a portion of the display panel 1000, and thus a biometric recognition function may be performed by absorbing light of a certain wavelength spectrum from any portion of the screen and converting it into an electrical signal, or, depending on the user's choice, the biometric recognition function may be selectively performed only at a specific location where the biometric recognition function is required.

An example of a method of recognizing the recognition target 90 in an electronic device 2000 such as a display device may include, for example, driving the first, second, and third light emitting elements 210, 220, and 230 of the display panel 1000 and the sensor 100 to sense the light reflected from the recognition target 90 among the light emitted from the first, second, and third light emitting elements 210, 220, and 230, in the sensor 100; comparing the image of the recognition target 90 stored in advance with the image of the recognition target 90 sensed by the sensor 100; and judging the consistency of the compared images and if they match according to the determination that recognition of the recognition target 90 is complete, turning off the sensor 100, permitting user's access to the display device, and driving the display panel 1000 to display an image.

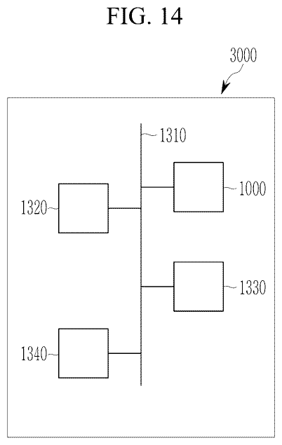

FIG. 14 is a schematic view illustrating an electronic device according to some example embodiments.

Referring to FIG. 14, in addition to the aforementioned constituent elements, the electronic device 3000 may further include a bus 1310, a processor 1320, a memory 1330, and at least one additional device 1340. Information of the aforementioned display panel 1000, processor 1320, memory 1330, and at least one additional device 1340 may be transmitted to each other through the bus 1310.

The processor 1320 may include one or more processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. As an example, the processing circuitry may include a non-transitory computer readable storage device. The processor 1320 may, for example, control a display operation of the display panel 1000 or control a sensor operation of the sensor 100.

The memory 1330 may store an instruction program, and the processor 1320 may perform a function related to the display panel 1000 by executing the stored instruction program.

The at least one additional device 1340 may be one or more communication interfaces (e.g., wireless communication interfaces, wired interfaces), user interfaces (e.g., keyboard, mouse, buttons, etc.), power supply and/or power supply interfaces, or any combination thereof.

The units and/or modules described herein may be implemented using hardware constituent elements and software constituent elements. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

The method according to the foregoing example embodiments may be recorded in a non-transitory computer readable storage device including program instructions for implementing various operations of the aforementioned embodiments. The storage device may also include program instructions, data files, data structures, and the like alone or in combination. The program instructions recorded in the storage device may be specially designed for the present example embodiments or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of any of the aforementioned example embodiments.

The aforementioned sensor 100 or the display panel 1000 also may be applied to an optical communication device as one example of an electronic device.

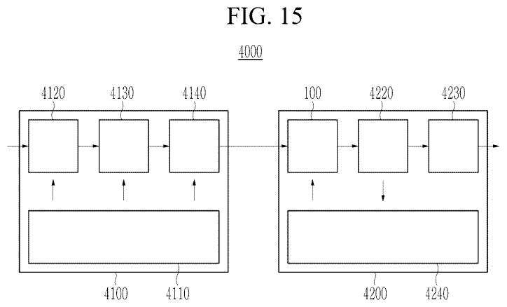

FIG. 15 is a schematic view showing an optical communication device as an electronic device according to some example embodiments.

Referring to FIG. 15, an optical communication device 4000 according to some example embodiments may include a transmitter 4100 and a receiver 4200. The transmitter 4100 may include a controller 4110, an encoder 4120, a pre-equalizer 4130, and a driver 4140. The receiver 4200 may include the aforementioned sensor 100 (or the display panel 1000, the image sensor 300, the image sensor 400, the image sensor 500, the image sensor 600), a machine learning demodulator 4220, a decoder 4230, and a signal-to-interference and noise ratio (SINR) estimator 4240.

The controller 4110 of the transmitter 4100 may determine a transmission parameter for encoding, equalizing, and optical signal driving and transmit the determined transmission parameter to the encoder 4120, the pre-equalizer 4130, and the driver 4140. The transmission parameter determined by the controller 4110 may include a modulation level for the encoding, an equalization parameter for the pre-equalizing, and a modulation depth for the optical signal driving. For example, the controller 4110, which receives a feedback of the estimated SINR of the received signals from the receiver 4200, may adjust the modulation level, the equalization parameter, and the modulation depth based on the received SINR feedback and then, transmit the adjusted modulation level, equalization parameter, and modulation depth to the encoder 4120, the pre-equalizer 4130, and the driver 4140.

The encoder 4120 of the transmitter 4100 may encode a bit string to be transmitted to the receiver 4200 according to a modulation level determined by the controller 4110 to generate encoded signals. The pre-equalizer 4130 of the transmitter 4100 may reinforce some frequency bands of the encoded signals to supplement reception characteristics of the sensor 100. The pre-equalizer 4130 may enhance a band corresponding to an enhanced bandwidth (i.e., pre-equalization parameter) determined by the controller 4110 in the encoded signals. The pre-equalizer 4130 may pre-equalize the optical signals based on a particular (or, alternatively, predetermined) equalization bandwidth (equalization parameter) and then, re-equalize (i.e., re-pre-equalize) the optical signals according to an adjusted equalization bandwidth based on the SINR feedback from the receiver 4200.

The driver 4140 of the transmitter 4100 may modulate electric signals depending on a modulation depth determined by the controller 4110 and drive the modulated signals to a light source (LED or laser, etc.). Subsequently, the light source driven by the driver 4140 may output the optical signals.

The sensor 100 of the receiver 4200 may be configured to convert light received from transmitter 4100 to electrical signals. The sensor 100 may be configured to convert light of different wavelength spectra sequentially or simultaneously to the electrical signals. If the light of different wavelength spectra is sequentially received by the receiver 4200, the sensor 100 may generate electrical signals according to each wavelength spectrum through the photoelectric conversion layer 30 corresponding to each wavelength spectrum. Or, if the light of different wavelength spectra simultaneously reach the receiver 4200, the sensor 100 may generate electrical signals according to each wavelength spectrum through the photoelectric conversion layer 30 corresponding to each wavelength spectrum. The sensor 100 may have the same structure as described above and exhibit further improved sensitivity by the first organic auxiliary layers 35 including the singlet fission material.

The ML demodulator 4220 of the receiver 4200 may demodulate original signals by using an ML model learned through sample data from the electrical signals converted by the sensor 100. The decoder 4230 of the receiver 4200 may decode bits from the demodulated electric signals. The SINR estimator 4240 of the receiver 4200 may estimate SINR of light from the demodulated electrical signals and then, feedback the estimated SINR to the transmitter 4100.

Hereinafter, some example embodiments are illustrated in more detail with reference to examples. However, the present scope of the inventive concepts is not limited to these examples.

### Manufacture of Sensor I

### Example 1

ITO is deposited on a glass substrate to form a 150 nm-thick anode (work function: 4.9 eV). Subsequently, on the anode, HT211 is thermally deposited to form a 15 nm-thick hole auxiliary layer (HOMO: 5.35 eV, LUMO: 2.08 eV). Then, Compound P (p-type semiconductor) and fullerene (C60, n-type semiconductor) in a volume ratio (thickness ratio) of 1:1 are co-deposited thereon to form a 50 nm-thick photoelectric conversion layer. Subsequently, Compound 1A (first singlet fission material) is thermally deposited thereon to form a 10 nm-thick first organic auxiliary layer, BCP is thermally deposited thereon to form a 15 nm-thick electron auxiliary layer, and ITO is deposited thereon to form a 7 nm-thick cathode (work function: 4.7 eV), manufacturing a sensor.

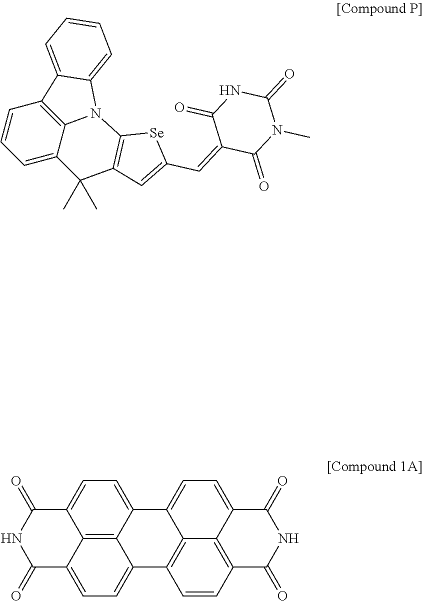 [SMILES: CN1C(=O)NC(=O)/C(=C\c2cc3c([se]2)-n2c4ccccc4c4cccc(c42)C3(C)C)C1=O ; O=C1NC(=O)c2ccc3c4ccc5c6c(ccc(c7ccc1c2c73)c64)C(=O)NC5=O]

### Example 2

A sensor is manufactured in the same manner as in Example 1 except that a 30 nm-thick first organic auxiliary layer is formed instead of the 10 nm-thick first organic auxiliary layer.

### Example 3

A sensor is manufactured in the same manner as in Example 1 except that a 50 nm-thick first organic auxiliary layer is formed instead of the 10 nm-thick first organic auxiliary layer.

### Example 4

A sensor is manufactured in the same manner as in Example 1 except that a 50 nm-thick first organic auxiliary layer is formed instead of the 10 nm-thick first organic auxiliary layer and additionally tetracene (Manufacturer: TCI) (a second singlet fission material) is thermally deposited between the hole auxiliary layer and the photoelectric conversion layer to form a 30 nm-thick second organic auxiliary layer.

### Example 5

A sensor is manufactured in the same manner as in Example 1 except that Compound 1B (first singlet fission material) is thermally deposited instead of Compound 1A (first singlet fission material) to form a 50 nm-thick first organic auxiliary layer.

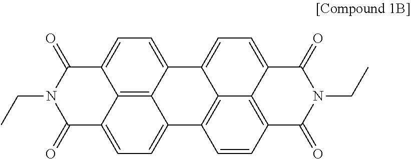 [SMILES: CCN1C(=O)c2ccc3c4ccc5c6c(ccc(c7ccc(c2c37)C1=O)c64)C(=O)N(CC)C5=O]

### Reference Example 1

A sensor is manufactured in the same manner as in Example 1 except that the first organic auxiliary layer is not formed.

### Reference Example 2

A sensor is manufactured in the same manner as in Example 1 except that Compound 1A (first singlet fission material) is thermally deposited on the hole auxiliary layer before forming the photoelectric conversion layer to form a 30 nm thick first organic auxiliary layer between the hole auxiliary layer and the photoelectric conversion layer, instead of forming the first organic auxiliary layer on the photoelectric conversion layer.

### Evaluation I

The p-type semiconductor, the n-type semiconductor, and the first and second singlet fission materials used in Examples are evaluated with respect to an energy level and an exciton energy in the singlet or triplet state.

A HOMO energy level is evaluated by irradiating UV light to the thin films by using AC-3 (Riken Keiki Co., LTD.) to measure an amount of photoelectrons emitted according to an energy.

After obtaining an energy bandgap by using a UV-Vis spectrometer (Shimadzu Corporation), a LUMO energy level is calculated by using the energy bandgap and the measured HOMO energy level.

The exciton energy (E(S₁)) in the singlet state or the exciton energy (E(T₁)) in the triplet state is DFT calculation values by using DGDZVP basis sets under B3LYP functional conditions.

The results are shown in Tables 2 and 3.

TABLE 2

| | HOMO | LUMO |
|---|---|---|
| | level (eV) | level (eV) |
| p-type semiconductor (Compound P) | 5.61 | 3.52 |
| n-type semiconductor (Fullerene) | 6.40 | 4.23 |
| First singlet fission material (Compound 1A) | 6.38 | 4.44 |
| First singlet fission material (Compound 1B) | 6.50 | 4.25 |
| Second singlet fission material (Tetracene) | 5.41 | 3.15 |

TABLE 3

| | E (S₁, eV) | E (T₁, eV) |
|---|---|---|
| p-type semiconductor (compound P) | 2.70 | 1.82 |
| n-type semiconductor (fullerene) | 2.46 | 1.95 |
| First singlet fission material (Compound 1A) | 2.549 | 1.494 |
| First singlet fission material (Compound 1B) | 2.537 | 1.486 |
| Second singlet fission material (Tetracene) | 2.69 | 1.46 |

### Evaluation II

The sensors according to Examples 1 to 5 and Reference Examples 1 and 2 are evaluated with respect to external quantum efficiency (EQE).

The EQEs of the sensors are evaluated by using Incident Photon to Current Efficiency (IPCE).

The results are shown in Table 4.

TABLE 4

| | λ_{peak, EQE} | EQE @3 V | FWHM_{EQE} |
|---|---|---|---|
| | (nm) | (%) | (nm) |
| Example 1 | 525 | 42.6 | 106 |
| Example 2 | 525 | 52.1 | 109 |
| Example 3 | 530 | 63.8 | 115 |
| Example 4 | 525 | 59.6 | 115 |
| Example 5 | 520 | 57.7 | 111 |
| Reference Example 1 | 518 | 26.6 | 107 |
| Reference Example 2 | 540 | 11.5 | 113 |

* λ_{peak, EQE}: Wavelength exhibiting maximum external quantum efficiency (EQE)
* FWHM_{EQE}: Full Width Half Maximum of EQE spectrum

Referring to Table 4, the sensors according to Examples, compared with the sensors according to Reference Example, exhibit an equivalent or improved full width at half maximum (FWHM) and improved external quantum efficiency (EQE).

Accordingly, the sensors according to Examples may be expected to implement improved sensitivity by exhibiting high external quantum efficiency in a relatively narrow wavelength region.

### Evaluation III

The sensors of Examples 1 to 5 and Reference Examples 1, 2 are evaluated with respect to internal quantum efficiency (IQE).

The internal quantum efficiency (IQE) of the sensors may be obtained by calculating absorbance (A) of the sensors and then, dividing the external quantum efficiency (EQE) by the absorption (A). The absorption (A) may be obtained through Relation Formula 2, and in Relation Formula 2, transmittance (T) and reflectance (R) may be obtained by using a UV-Vis spectrometer (Shimadzu Corporation).

$$A = 100 - T - R \qquad [ Relation Formula 2 ]$$

In Relation Formula 2, A is absorbance, T is transmittance, and R is reflectance.

The results are shown in Table 5.

TABLE 5

| | λ_{peak, IQE} | IQE @3 V | FWHM_{IQE} |
|---|---|---|---|
| | (nm) | (%) | (nm) |
| Example 1 | 525 | 70.0 | 142 |
| Example 2 | 525 | 72.8 | 132 |
| Example 3 | 530 | 80.0 | 140 |
| Example 4 | 538 | 75.6 | 180 |
| Example 5 | 535 | 83.7 | 180 |
| Reference Example 1 | 481 | 61.6 | 261 |
| Reference Example 2 | 545 | 16.3 | — |

* λ_{peak, IQE}: Wavelength exhibiting maximum internal quantum efficiency (IQE)
* FWHM_{IQE}: Full Width Half Maximum of IQE spectrum

Referring to Table 5, the sensors according to Examples 1 to 5, compared with the sensors according to Reference Examples 1 and 2, exhibit an improved full width at half maximum (FWHM) and internal quantum efficiency (IQE). Accordingly, the sensors according to Examples may be expected to implement improved sensitivity by exhibiting high internal quantum efficiency in a relatively narrow wavelength region.

As described herein, any devices, systems, modules, portions, units, controllers, circuits, and/or portions thereof according to any of the example embodiments, and/or any portions thereof (including, without limitation, electronic device 2000, display panel 1000, sensor 100, electronic device 3000, processor 1320, memory 1330, at least one additional device 1340, optical communication device 4000, transmitter 4100, controller 4110, encoder 4120, pre-equalizer 4130, driver, receiver 4200, machine learning demodulator 4220, decoder 4230, signal-to-interference and noise ratio (SINR) estimator 4240, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

While the inventive concepts have been described in connection with what is presently considered to be practical example embodiments, it is to be understood that the inventive concepts are not limited to such example embodiments. On the contrary, the scope of the inventive concepts is intended to cover various modifications and equivalent arrangements included within the spirit and scope of the appended claims.

What is claimed is:

1. A sensor, comprising:
an anode;
a cathode;
an organic photoelectric conversion layer between the anode and the cathode, the organic photoelectric conversion layer including a p-type semiconductor and an n-type semiconductor; and
a first organic auxiliary layer between the cathode and the organic photoelectric conversion layer, the first organic auxiliary layer including a first singlet fission material,
wherein a LUMO energy level of the first singlet fission material is equal to or deeper than a LUMO energy level of the n-type semiconductor, and
wherein the first singlet fission material is represented by Chemical Formula 1: 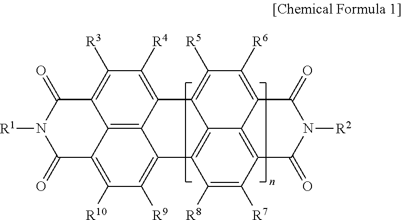
wherein, in the Chemical Formula 1,
R¹ to R¹⁰ are each independently hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a substituted or unsubstituted silyl group, a substituted or unsubstituted amine group, a halogen, a cyano group, or any combination thereof,
R¹ to R¹⁰ are each independently present or two adjacent ones among R¹ to R¹⁰ are linked to form a ring, and
n is an integer from 0 to 3.

2. The sensor of claim 1, wherein the first organic auxiliary layer is in contact with the organic photoelectric conversion layer.

3. The sensor of claim 1, wherein the LUMO energy level of the first singlet fission material is between the LUMO energy level of the n-type semiconductor and a work function of the cathode.

4. The sensor of claim 1, wherein the first singlet fission material and at least one of the p-type semiconductor or the n-type semiconductor are each a wavelength-selective organic material configured to selectively absorb light of a first wavelength spectrum selected from a blue wavelength spectrum, a green wavelength spectrum, a red wavelength spectrum, and an infrared wavelength spectrum.

5. The sensor of claim 4, wherein
the first singlet fission material and the at least one of the p-type semiconductor or the n-type semiconductor are each an organic material configured to absorb light in the green wavelength spectrum, and
a wavelength (λ_{max, EQE}) exhibiting a maximum external quantum efficiency of the sensor and a wavelength (λ_{max, IQE}) exhibiting a maximum internal quantum efficiency of the sensor each belong to about 510 nm to about 580 nm.

6. The sensor of claim 1, further comprising an electron auxiliary layer between the first organic auxiliary layer and the cathode,
wherein a HOMO energy level of the electron auxiliary layer is deeper than each of a work function of the cathode and a HOMO energy level of the p-type semiconductor.

7. The sensor of claim 1, further comprising a second organic auxiliary layer between the anode and the organic photoelectric conversion layer,
wherein the second organic auxiliary layer comprises a second singlet fission material different from the first singlet fission material.

8. The sensor of claim 7, wherein the second singlet fission material is an organic material that satisfies Relation Formula 1:
$$E ( {S}_{1} ) + 0.5 eV \geq 2 \times E ( {T}_{1} ) \qquad [ Relation Formula 1 ]$$
wherein, in Relation Formula 1,
E(S₁) is an excitation energy in a lowest singlet excited state of the second singlet fission material,
E(T₁) is an excitation energy in a lowest triplet excited state of the second singlet fission material, and
E(S₁) and E(T₁) are DFT calculation values.

9. The sensor of claim 8, wherein the p-type semiconductor and the n-type semiconductor each do not satisfy an energy level of the Relation Formula 1.

10. The sensor of claim 7, wherein
the second organic auxiliary layer is in contact with the organic photoelectric conversion layer, and
a HOMO energy level of the second singlet fission material is equal to or shallower than a HOMO energy level of the p-type semiconductor.

11. The sensor of claim 10, wherein the HOMO energy level of the second singlet fission material is between the HOMO energy level of the p-type semiconductor and a work function of the anode.

12. The sensor of claim 7, further comprising a hole auxiliary layer between the second organic auxiliary layer and the anode,
wherein a LUMO energy level of the hole auxiliary layer is shallower than each of a work function of the anode and the LUMO energy level of the n-type semiconductor.

13. An image sensor, comprising:
a substrate, and
the sensor of claim 1 on the substrate.

14. The image sensor of claim 13, further comprising a first photodiode and a second photodiode within the substrate,
wherein the first photodiode and the second photodiode each overlap the sensor along a thickness direction of the substrate.

15. The image sensor of claim 14, further comprising:
a first color filter between the sensor and the first photodiode, and
a second color filter between the sensor and the second photodiode.

16. The image sensor of claim 14, wherein the sensor comprises:
a first sensor configured to photoelectrically convert light of a first wavelength spectrum selected from a red wavelength spectrum, a green wavelength spectrum, and a blue wavelength spectrum,
a second sensor configured to photoelectrically convert light of a second wavelength spectrum selected from the red wavelength spectrum, the green wavelength spectrum, and the blue wavelength spectrum, and
a third sensor configured to photoelectrically convert light of a third wavelength spectrum selected from the red wavelength spectrum, the green wavelength spectrum, and the blue wavelength spectrum,
wherein the first wavelength spectrum, the second wavelength spectrum, and the third wavelength spectrum are different from each other, and
wherein the first sensor, the second sensor, and the third sensor are stacked along the thickness direction of the substrate.

17. A display panel, comprising:
a substrate,
a light emitting element array on the substrate, the light emitting element array including
a blue light emitting element configured to emit light in a blue wavelength spectrum,
a green light emitting element configured to emit light in a green wavelength spectrum, and
a red light emitting element configured to emit light in a red wavelength spectrum, and
a sensor array on the substrate, the sensor array including the sensor of claim 1.

18. A device comprising the sensor of claim 1.

19. A device comprising the image sensor of claim 13.

20. A device comprising the display panel of claim 17.
